(19) United States
(12) Patent Application Publication
(10) Pub. No.: US 2023/0299116 A1
(43) Pub. Date: Sep. 21, 2023

(54) IMAGE SENSOR

(71) Applicant: SAMSUNG ELECTRONICS CO., LTD., Suwon-si (KR)

(72) Inventors: Jungwook Lim, Suwon-si (KR); Joongseok Park, Suwon-si (KR); Dongsuk Yoo, Suwon-si (KR); Seojoo Kim, Suwon-si (KR); Soeun Park, Suwon-si (KR); Sunghyuck Cho, Suwon-si (KR)

(73) Assignee: SAMSUNG ELECTRONICS CO., LTD., Suwon-si (KR)

(21) Appl. No.: 18/123,073

(22) Filed: Mar. 17, 2023

(30) Foreign Application Priority Data
Mar. 17, 2022 (KR) 10-2022-0033547
May 25, 2022 (KR) 10-2022-0063976
Feb. 8, 2023 (KR) 10-2023-0016917

(51) Int. Cl. H01L 27/146

(52) U.S. Cl. CPC H01L 27/14654; H01L 27/14645; H01L 27/14621; H01L 27/1463

(57) ABSTRACT

Disclosed is an image sensor including a semiconductor substrate including first and second pixel regions, first and second photoelectric conversion elements on the first and second pixel regions, a pixel isolation structure between the first and second photoelectric conversion elements, a first floating diffusion region on the first pixel region, a first transfer gate electrode between the first photoelectric conversion element and the first floating diffusion region, a second floating diffusion region on the second pixel region, a second transfer gate electrode between the second photoelectric conversion element and the second floating diffusion region, a first charge storage region on the first pixel region, a second charge storage region on the second pixel region, a first switching element between the first floating diffusion region and the first charge storage region, and a second switching element between the second floating diffusion region and the second charge storage region.

### CROSS-REFERENCE TO RELATED APPLICATIONS

This application is based on and claims priority under 35 U.S.C § 119 to Korean Patent Applications No. 10-2022-0033547 filed on Mar. 17, 2022, No. 10-2022-0063976 filed on May 25, 2022, and No. 10-2023-0016917 filed on Feb. 8, 2023 in the Korean Intellectual Property Office, the disclosures of which are incorporated by reference herein in their entireties.

### BACKGROUND

The disclosure relates to an image sensor, and more particularly, to an image sensor having enhanced blooming properties.

An image sensor converts photonic images into electrical signals. Recent advances in computer and communication industries have led to strong demands in high performance image sensors in various consumer electronic devices such as digital cameras, camcorders, PCSs (personal communication systems), game consoles, security cameras, and medical micro-cameras.

An image sensor is classified as a charged coupled device (CCD) or a CMOS image sensor. The CMOS image sensor has a simple operating method, and a size of its product is possibly minimized because its signal processing circuit is integrated into a single chip. Also, the CMOS image sensor requires relatively small power consumption, which is useful in battery-powered application. In addition, since process technology of manufacturing CMOS image sensors is compatible with CMOS process technology, the CMOS image sensors can have decreased fabrication cost. Accordingly, the use of the CMOS image sensor has been rapidly increasing as a result of advanced in technology and implementation of high resolution.

### SUMMARY

Some embodiments of the disclosure provide an image sensor with high dynamic range and improved blooming properties.

The object of the disclosure is not limited to that mentioned above, and other objects which have not been mentioned above will be clearly understood to those skilled in the art from the following description.

In accordance with an aspect of the disclosure, an image sensor may include a semiconductor substrate including a first pixel region and a second pixel region; a first photoelectric conversion element on the first pixel region; a second photoelectric conversion element on the second pixel region; a pixel isolation structure between the first photoelectric conversion element and the second photoelectric conversion element; a first floating diffusion region on the first pixel region; a first transfer gate electrode between the first photoelectric conversion element and the first floating diffusion region; a second floating diffusion region on the second pixel region; a second transfer gate electrode between the second photoelectric conversion element and the second floating diffusion region; a first charge storage region on the first pixel region; a second charge storage region on the second pixel region; a first switching element between the first floating diffusion region and the first charge storage region; and a second switching element between the second floating diffusion region and the second charge storage region.

In accordance with an aspect of the disclosure, an image sensor may include a semiconductor substrate including a first pixel region and a second pixel region, the semiconductor substrate having a first conductivity type; a first photoelectric conversion element on the first pixel region, the first photoelectric conversion element having a second conductivity type; a second photoelectric conversion element on the second pixel region, the second photoelectric conversion element having the second conductivity type; a pixel isolation structure between the first photoelectric conversion element and the second photoelectric conversion element; a first charge storage region on the first pixel region, the first charge storage region having the second conductivity type; a second charge storage region on the second pixel region, the second charge storage region having the second conductivity type; a first well impurity region in the semiconductor substrate between the first charge storage region and the first photoelectric conversion element, the first well impurity region having the first conductivity type and overlapping a portion of the first photoelectric conversion element; and a second well impurity region in the semiconductor substrate between the second charge storage region and the second photoelectric conversion element, the second well impurity region having the first conductivity type and overlapping a portion of the second photoelectric conversion element. A width of the second photoelectric conversion element may be less than a width of the first photoelectric conversion element.

In accordance with an aspect of the disclosure, an image sensor may include a semiconductor substrate including a first pixel region and a second pixel region, the semiconductor substrate having a first conductivity type; a first photoelectric conversion element on the first pixel region, the first photoelectric conversion element having a second conductivity type; a second photoelectric conversion element on the second pixel region, the second photoelectric conversion element having the second conductivity type; a pixel isolation structure between the first photoelectric conversion element and the second photoelectric conversion element; a first floating diffusion region on the first pixel region, the first floating diffusion region having the second conductivity type; a first transfer gate electrode between the first photoelectric conversion element and the first floating diffusion region; a first charge storage region on the first pixel region, the first charge storage region having the second conductivity type; a first switching element between the first floating diffusion region and the first charge storage region; a second floating diffusion region on the second pixel region, the second floating diffusion region having the second conductivity type; a second transfer gate electrode between the second photoelectric conversion element and the second floating diffusion region; a second charge storage region on the second pixel region, the second charge storage region having the second conductivity type; a second switching element between the second floating diffusion region and the second charge storage region; a first well impurity region in the semiconductor substrate between the first charge storage region and the first photoelectric conversion element, the first well impurity region having the first conductivity type and overlapping a portion of the first photoelectric conversion element; a second well impurity region in the semiconductor substrate between the second charge storage region and the second photoelectric conversion element, the second well impurity region having the first conductivity type and overlapping a portion of the second photoelectric conversion element; a conductive line that connects the first charge storage region to the second charge storage region; and a capacitor connected to the second floating diffusion region.

### BRIEF DESCRIPTION OF DRAWINGS

FIG. 1 illustrates a block diagram showing an image sensor according to some embodiments of the disclosure.

FIGS. 2A and 2B illustrate circuit diagrams showing a unit pixel of a pixel array according to some embodiments of the disclosure.

FIGS. 3A and 3B illustrate cross-sectional views showing an image sensor according to some embodiments of the disclosure.

FIG. 4 illustrates a plan view showing a unit pixel of an image sensor according to some embodiments of the disclosure.

FIGS. 5A and 5B illustrate cross-sectional views showing an image sensor according to some embodiments of the disclosure.

FIG. 6 illustrates a plan view showing an image sensor according to some embodiments of the disclosure.

FIG. 7 illustrates a timing diagram showing an operation of an image sensor according to some embodiments of the disclosure.

FIG. 8 illustrates a circuit diagram showing a unit pixel of a pixel array according to some embodiments of the disclosure.

FIG. 9 illustrates a cross-sectional view showing an image sensor according to some embodiments of the disclosure.

FIG. 10 illustrates a plan view showing a unit pixel of the image sensor depicted in FIG. 9.

FIG. 11 illustrates a potential diagram of the image sensor depicted in FIG. 10.

FIG. 12 illustrates a cross-sectional view showing an image sensor according to some embodiments of the disclosure.

FIG. 13 illustrates a plan view showing a unit pixel of the image sensor depicted in FIG. 12.

FIG. 14 illustrates a potential diagram of the image sensor depicted in FIGS. 12 and 13.

FIGS. 15A and 15B illustrate simplified perspective views showing an image sensor according to some embodiments of the disclosure.

FIGS. 16A and 16B illustrate cross-sectional views showing an image sensor according to some embodiments of the disclosure.

### DETAILED DESCRIPTION OF EMBODIMENTS

Disclosed are an image sensor and an operating method thereof according to some embodiments of the disclosure in conjunction with the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

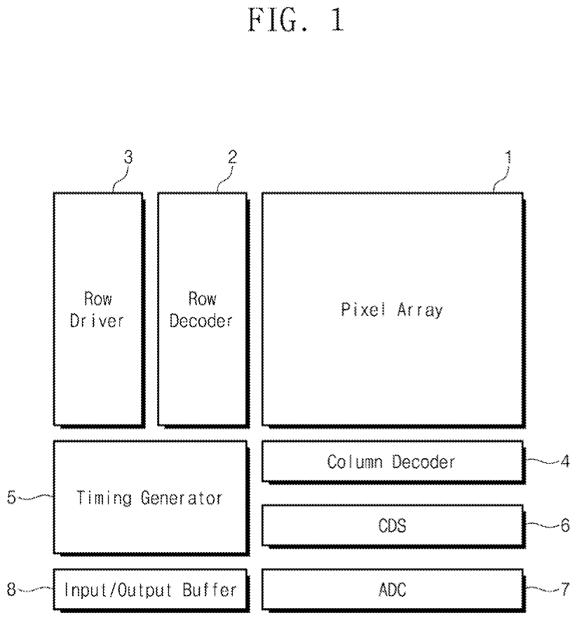

FIG. 1 illustrates a block diagram showing an image sensor according to some embodiments of the disclosure.

Referring to FIG. 1, an image sensor may include a pixel array 1, a row decoder 2, a row driver 3, a column decoder 4, a timing generator 5, a correlated double sampler (CDS) 6, an analog-to-digital converter (ADC) 7, and an input/output (I/O) buffer 8.

The pixel array 1 may include a plurality of unit pixels arranged along rows and columns, and may convert lights incident on the unit pixels into electrical signals. The pixel array 1 may be driven by a plurality of drive signals such as a selection signal, a reset signal, and a transfer signal that are provided from the row driver 2.

The row decoder 2 may provide several drive signals to each row of the unit pixels. In response to the drive signals, the correlated double sampler 6 may be provided with electrical signals converted in the pixel array 1.

In accordance with a decoded result obtained from the row decoder 2, the row driver 3 may provide the pixel array 1 with several drive signals for driving several unit pixels. When the unit pixels are arranged in a matrix shape, the drive signals may be provided to each row.

The timing generator 5 may control the row and column decoders 2 and 4, the correlated double sampler 6, the analog-to-digital converter 7, and the input/output buffer 8, which are supplied by the timing generator 5 with control signals such as a clock signal, a timing control signal, and/or other signals. The timing generator 5 may include a logic control circuit, a phase lock loop (PLL) circuit, a timing control circuit, a communication interface circuit, and/or other circuits.

The correlated double sampler 6 may receive the electrical signals generated in the pixel array 1, and may hold and sample the received electrical signals. The correlated double sampler 6 may perform a double sampling operation to sample a specific noise level and a signal level of the electrical signal, and then output a difference level corresponding to a difference between the noise and signal levels.

The analog-to-digital converter (ADC) 7 may convert analog signals, which correspond to the difference level received from the correlated double sampler 6, into digital signals, and then may output the converted digital signals.

The input/output buffer 8 may latch the digital signals and then sequentially output the latched digital signals to an image signal processing unit in response to the decoded result obtained from the column decoder 4.

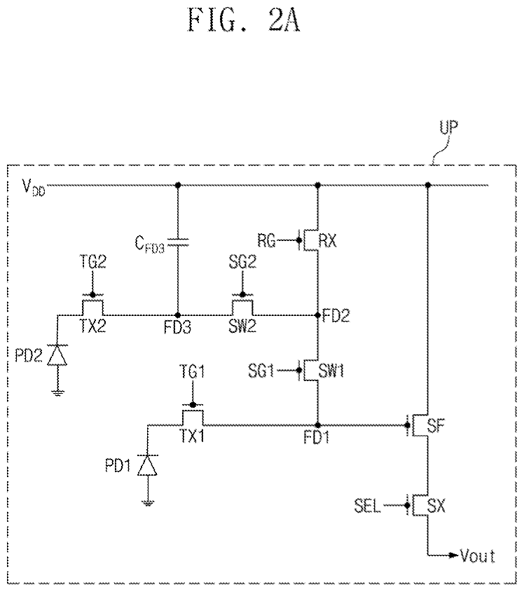

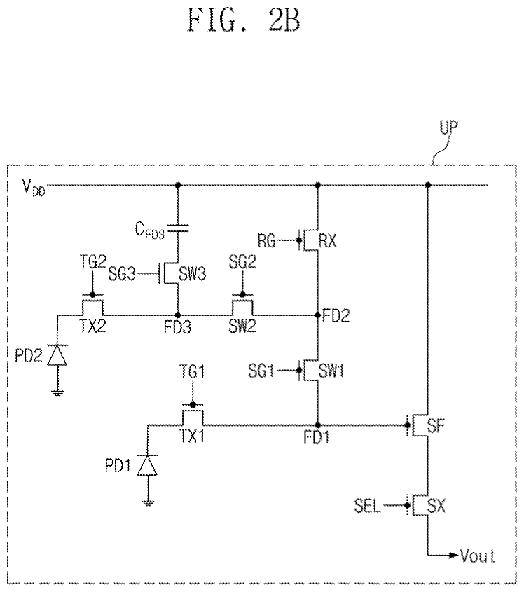

FIGS. 2A and 2B illustrate circuit diagrams showing a unit pixel of a pixel array according to some embodiments of the disclosure.

Referring to FIG. 2A, a unit pixel P may include first and second photoelectric conversion elements PD1 and PD2, first and second charge transfer transistors TX1 and TX2, and pixel transistors. The pixel transistors may include first and second switching transistors SW1 and SW2 (or switching elements), a capacitor C_{FD3} (or a charge storage element), a reset transistor RX, a source follower transistor SF, and a selection transistor SX. In some embodiments, in each unit pixel P, there may be a variation in the number of the pixel transistors.

The first and second photoelectric conversion elements PD1 and PD2 may generate and accumulate charges that correspond to intensity of incident light. The first and second photoelectric conversion elements PD1 and PD2 may each be one of a photodiode, a photo transistor, a photogate, a pinned photodiode (PPD), and any combination thereof.

The first transfer transistor TX1 may provide a first charge detection node FD1 (or a first floating diffusion region) with charges stored in the first photoelectric conversion element PD1.

The second transfer transistor TX2 may provide a third charge detection node FD3 (or a third floating diffusion region) with charges stored in the second photoelectric conversion element PD2. The second charge detection node FD2 will be described later.

When the second transfer transistor TX2 is turned on, charges generated from the second photoelectric conversion element PD2 may be accumulated or stored in the capacitor C_{FD3}.

The first and second transfer transistors TX1 and TX2 may be controlled with first and second transfer signals TG1 and TG2.

The first charge detection node FD1 may receive and accumulate charges generated from the first photoelectric conversion element PD1. The source follower transistor SF may be controlled by an amount of photo-charges accumulated in the first charge detection node FD1.

The first switching transistor SW1 may be connected between the first charge detection node FD1 and a second charge detection node FD2 (or a second floating diffusion region). The first switching transistor SW1 may be connected in series through the second charge detection node FD2 to the reset transistor RX. In response to a first switching signal SG1, the first switching transistor SW1 may change a capacitance of the first charge detection node FD1, thereby changing a conversion gain of the unit pixel P.

The second switching transistor SW2 may be connected between the second charge detection node FD2 and the third charge detection node FD3 (or a third floating diffusion region). In response to a second switching signal SG2, the second switching transistor SW2 may change a capacitance of the third charge detection node FD3, thereby changing a conversion gain of the unit pixel P.

The capacitor C_{FD3} may be connected between the third charge detection node FD3 and a pixel power voltage V_{DD}. The capacitor C_{FD3} may be, for example, a metal-oxide-semiconductor (MOS) capacitor, a metal-insulator-semiconductor (MIS) capacitor, or a metal-insulator-metal (MIM) capacitor. In response to an amount of charges generated from the second photoelectric conversion element PD2 and an operation of the second transfer transistor TX2, the capacitor C_{FD3} may store charges.

Referring to FIG. 2B, the unit pixel P may further include a third switching transistor SW3 between the capacitor C_{FD3} (or a charge storage element) and the third charge detection node FD3. In response to a third switching signal SG3, the third switching transistor SW3 may change a capacitance of the third charge detection node FD3, thereby changing a conversion gain of the unit pixel P.

The reset transistor RX may be controlled by a reset signal RG, and in accordance with the reset signal RG, may periodically reset charges accumulated in the second charge detection node FD2. For example, the reset transistor RX may have a drain terminal connected to the second charge detection node FD2 and a source terminal connected to the pixel power voltage V_{DD}.

When the reset transistor RX is turned on, the pixel power voltage V_{DD} may be transmitted to the second charge detection node FD2. Therefore, charge accumulated in the second charge detection node FD2 may be exhausted to reset the second charge detection node FD2. In addition, based on on/off of the first switching transistor SW1, the pixel power voltage V_{DD} may be transmitted to the first charge detection node FD1 and thus the first charge detection node FD1 may be reset. Moreover, based on on/off's of the first and second switching transistors SW1 and SW2, the first, second, and third charge detection nodes FD1, FD2, and FD3 may be reset.

The source follower transistor SF may be a source follower buffer amplifier that generates a source-drain current in proportion to an amount of charges applied to a source follower gate electrode from the first charge detection node FD1. The source follower transistor SF may amplify a variation in electrical potential of the first charge detection node FD1 and output the amplified signal through the selection transistor SX. The source follower transistor SF may have a source terminal connected to the pixel power voltage V_{DD} and a drain terminal connected to a source terminal of the selection signal SEL.

The selection transistor SX may select each row of the unit pixel P to be readout. When the selection transistor SX is turned on in response to a selection signal SEL applied to a selection gate electrode, an output line V_{OUT} may output an electrical signal that is output from the drain terminal of the source follower transistor SF.

According to some embodiments, the first, second, and third switching transistors SW1, SW2, and SW3 may adjust a conversion gain of the unit pixel P.

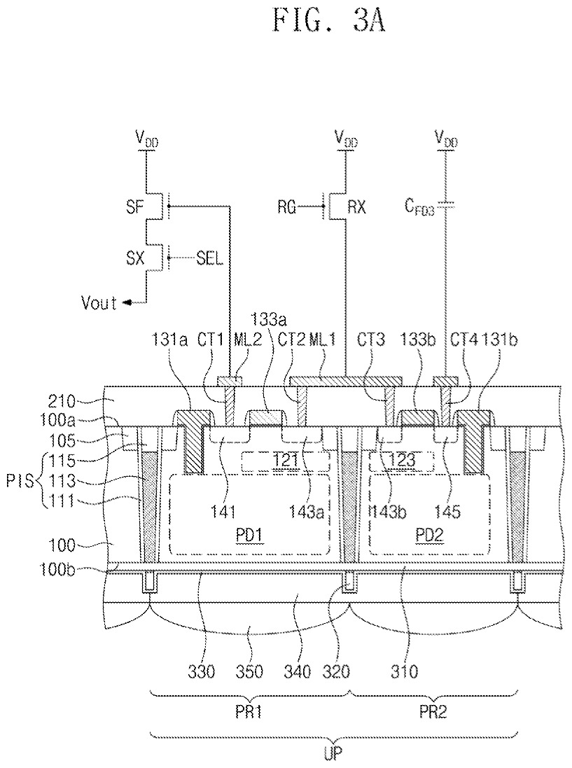

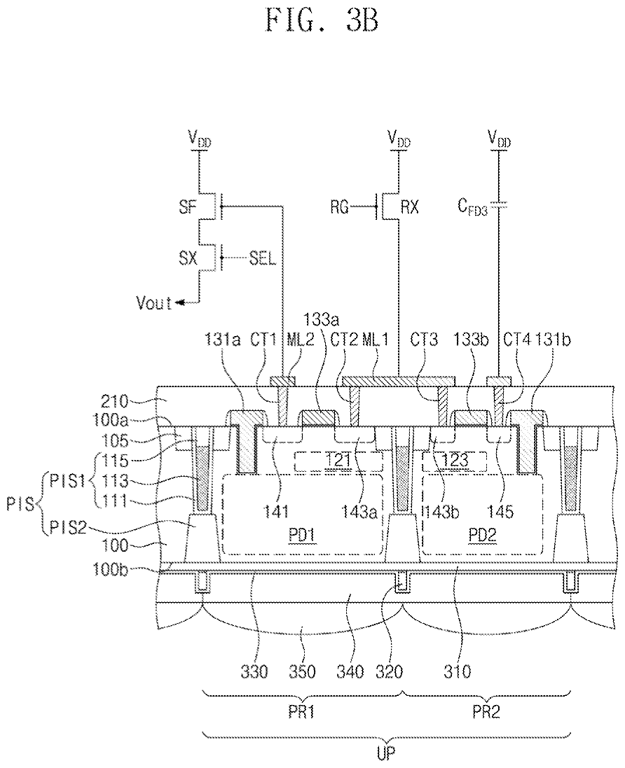

FIGS. 3A and 3B illustrate cross-sectional views showing an image sensor according to some embodiments of the disclosure.

Referring to FIG. 3A, a semiconductor substrate 100 may have a first surface (or a front surface) 100a and a second surface (or a rear surface) 100b that are opposite to each other. The semiconductor substrate 100 may be an epitaxial layer formed on a bulk silicon substrate that has the same first conductivity type (e.g., p-type) as that of the epitaxial layer, or a p-type epitaxial layer from which a bulk silicon substrate is removed in fabrication of the image sensor. Alternatively, the semiconductor substrate 100 may be a bulk semiconductor substrate that includes a well of the first conductivity type.

The image sensor may include a plurality of pixel regions UP, and each pixel region UP may include first and second pixel regions PR1 and PR2. The first and second pixel regions PR1 and PR2 may be two-dimensionally arranged along rows and columns.

The semiconductor substrate 100 may be provided therein with a pixel isolation structure PIS that defines the first and second pixel regions PR1 and PR2. The pixel isolation structure PIS may be provided between the first and second pixel regions PR1 and PR2 of the semiconductor substrate 100. When viewed in plan, the pixel isolation structure PIS may surround each of the first and second pixel regions PR1 and PR2.

The pixel isolation structure PIS may have a top surface substantially coplanar with the first surface 100a of the semiconductor substrate 100. The pixel isolation structure PIS may extend from the first surface 100a to the second surface 100b.

The pixel isolation structure PIS may be formed by patterning the first surface 100a of the semiconductor substrate 100 to form a deep trench, and then filling the deep trench with a liner dielectric layer and an impurity-doped semiconductor layer. In this case, the pixel isolation structure PIS may have a width that gradually decreases in a direction from the first surface 100a toward the second surface 100b of the semiconductor substrate 100. Alternatively, the pixel isolation structure PIS may have a width that is substantially constant between the first surface 100a and the second surface 100b of the semiconductor substrate 100.

In some embodiments, the pixel isolation structure PIS may be formed by patterning the second surface 100b of the semiconductor substrate 100 to form a deep trench, and then filling the deep trench with a liner dielectric layer and an impurity-doped semiconductor layer. In this case, the pixel isolation structure PIS may have a width that gradually increases in a direction from the first surface 100a toward the second surface 100b of the semiconductor substrate 100.

The pixel isolation structure PIS may be formed of a dielectric material whose refractive index is less than that of the semiconductor substrate 100 (e.g., silicon), and may include a single or plurality of dielectric layers.

The pixel isolation structure PIS may include a liner dielectric pattern 111, a semiconductor pattern 113, and a capping dielectric pattern 115. The semiconductor pattern 113 may vertically penetrate a portion of the semiconductor substrate 100, and the liner dielectric pattern 111 may be provided between the semiconductor pattern 113 and the semiconductor substrate 100. The capping dielectric pattern 115 may be disposed on the semiconductor pattern 113, and may have a top surface substantially coplanar with the first surface 100a of the semiconductor substrate 100.

The liner dielectric pattern 111 and the capping dielectric pattern 115 may include at least one selected from a silicon oxide layer, a silicon oxynitride layer, and a silicon nitride layer. The semiconductor pattern 113 may include an undoped polysilicon layer or an impurity-doped polysilicon layer. The semiconductor pattern 113 may have an air gap or a void.

The pixel isolation structure PIS may penetrate the semiconductor substrate 100. The pixel isolation structure PIS may vertically extend from the first surface 100a to the second surface 100b of the semiconductor substrate 100. For example, the pixel isolation structure PIS may have a vertical length in a direction perpendicular to a surface of the semiconductor substrate 100, and the vertical length may be substantially the same as a vertical thickness of the semiconductor substrate 100.

Alternatively, the pixel isolation structure PIS may vertically penetrate a portion of the semiconductor substrate 100, and may be spaced apart from the second surface 100b of the semiconductor substrate 100.

The pixel isolation structure PIS may prevent the first and second pixel regions PR1 and PR2 from receiving randomly drifting photo-charges that are generated by light that is incident on adjacent first and second pixel regions PR1 and PR2. In this configuration, the pixel isolation structure PIS may help prevent crosstalk between neighboring first and second pixel regions PR1 and PR2.

According to the embodiment illustrated in FIG. 3B, the pixel isolation structure PIS may include first and second pixel isolation structures PIS1 and PIS2. The first pixel isolation structure PIS1 may have substantially the same characteristics as those of the pixel isolation structure PIS discussed above with reference to FIG. 3A.

A portion of the liner dielectric pattern 111 of the first pixel isolation structure PIS1 may be in contact with the second pixel isolation structure PIS2, and may be disposed between the second pixel isolation structure PIS2 and the semiconductor pattern 113.

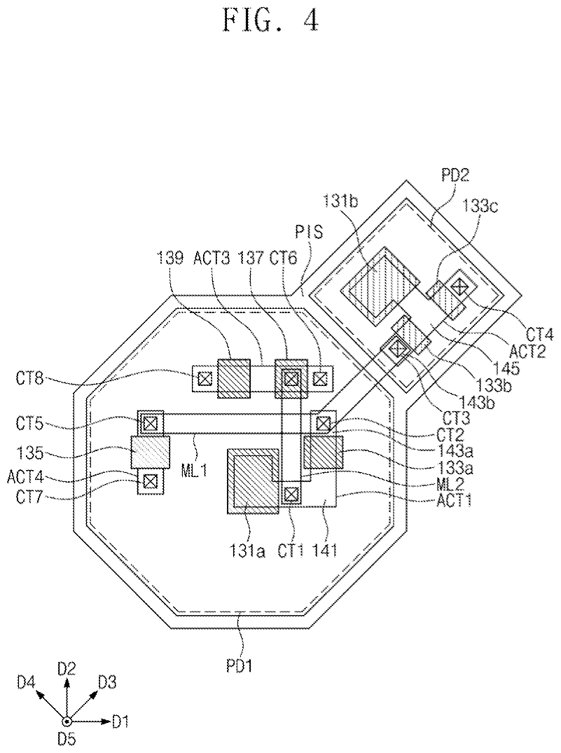

The second pixel isolation structure PIS2 may have a planar shape substantially the same as that of the first pixel isolation structure PIS1. When viewed in plan, the second pixel isolation structure PIS2 may overlap the first pixel isolation structure PIS1. For example, the second pixel isolation structure PIS2 may include first parts that extend in a first direction D1, and may also include second parts that intersect the first parts and extend in a second direction D2 (see, e.g., FIG. 4).

The second pixel isolation structure PIS2 may be provided in the semiconductor substrate 100, while extending in a vertical direction from the second surface 100b of the semiconductor substrate 100. The second pixel isolation structure PIS2 may be provided in a trench that is recessed from the second surface 100b of the semiconductor substrate 100.

The second pixel isolation structure PIS2 may have a bottom surface between the first surface 100a and the second surface 100b of the semiconductor substrate 100. For example, the second pixel isolation structure PIS2 may be spaced apart from the first surface 100a of the semiconductor substrate 100. The second pixel isolation structure PIS2 may be in contact with the first pixel isolation structure PIS1.

The second pixel isolation structure PIS2 may have a second upper width at the second surface 100b of the semiconductor substrate 100 and a second lower width at the bottom surface of the second pixel isolation structure PIS2. The second lower width may be substantially the same as or less than the second upper width. In other words, the second pixel isolation structure PIS2 may have a width that gradually decreases in a direction from the second surface 100b toward the first surface 100a of the semiconductor substrate 100.

When viewed in a vertical direction, the second pixel isolation structure PIS2 may have a length different from that of the first pixel isolation structure PIS1. For example, the length of the second pixel isolation structure PIS2 may be substantially the same as or less than the length of the first pixel isolation structure PIS1.

The second pixel isolation structure PIS2 may be formed of at least one high-k dielectric layer whose dielectric constant is greater than that of a silicon oxide layer. For example, the second pixel isolation structure PIS2 may include metal oxide or metal fluoride that includes at least one metal selected from hafnium (Hf), zirconium (Zr), aluminum (Al), tantalum (Ta), titanium (Ti), yttrium (Y), and lanthanide (Ln). For example, the second pixel isolation structure PIS2 may include an aluminum oxide layer and a hafnium oxide layer that are sequentially stacked.

According to some embodiments, a first photoelectric conversion region PD1 may be provided in the semiconductor substrate 100 on the first pixel region PR1. A second photoelectric conversion region PD2 may be provided in the semiconductor substrate 100 on the second pixel region PR2. The first and second photoelectric conversion regions PR1 and PR2 may convert externally incident light into electrical signals. In this description, the term “photoelectric conversion element” and the term “photoelectric conversion region” may be interchangeably used.

Each of the first and second photoelectric conversion regions PD1 and PD2 may be doped with impurities having a second conductivity type (e.g., n-type) opposite to the first conductivity type of the semiconductor substrate 100. Photodiodes may be constituted by the semiconductor substrate 100 of the first conductivity type and the first and second photoelectric conversion regions PD1 and PD2 of the second conductivity type.

For example, a photodiode may be constituted by a junction between the semiconductor substrate 100 of the first conductivity type and one of the first and second photoelectric conversion regions PD1 and PD2 of the second conductivity type. The first and second photoelectric conversion regions PD1 and PD2 that constitute the photodiodes may generate and accumulate photo-charges in proportion to intensity of incident light.

In some embodiments, the first photoelectric conversion region PD1 may have a light-receiving area greater than that of the second photoelectric conversion region PD2. For example, the first photoelectric conversion region PD1 may have a volume greater than that of the second photoelectric conversion region PD2.

The first photoelectric conversion region PD1 may have a first width in one direction, and the second photoelectric conversion region PD2 may have a second width, which is less than the first width, in the one direction. In addition, the first and second photoelectric conversion regions PD1 and PD2 may have substantially the same vertical depth.

When viewed in plan, each of the first and second photoelectric conversion regions PD1 and PD2 may be surrounded by the pixel isolation structure PIS. Therefore, photo-charges accumulated in the first and second photoelectric conversion regions PD1 and PD2 may be prevented from overflowing into adjacent first and second photoelectric conversion regions PD1 and PD2.

On each of the first and second pixel regions PR1 and PR2, a device isolation layer 105 may define at least one active section on the first surface 100a of the semiconductor substrate 100.

On each of the first and second pixel regions PR1 and PR2, the device isolation layer 105 may be disposed adjacent to the first surface 100a of the semiconductor substrate 100. The device isolation layer 105 may have a bottom surface spaced apart from the first and second photoelectric conversion regions PD1 and PD2.

The device isolation layer 105 may be provided in a trench that is formed by recessing the first surface 100a of the semiconductor substrate 100. The device isolation layer 105 may be formed of a dielectric material. For example, the device isolation layer 105 may include a liner oxide layer and a liner nitride layer that conformally cover a surface of the trench, and may also include a filling oxide layer that fills the trench in which the liner oxide layer and the oxide nitride layer are formed.

The device isolation layer 105 may have a top surface substantially coplanar with the first surface 100a of the semiconductor substrate 100. In addition, the top surface of the device isolation layer 105 may be substantially coplanar with that of the pixel isolation structure PIS. In this configuration, the top surface of the device isolation layer 105 may be substantially coplanar with the first surface 100a of the semiconductor substrate 100.

On the first pixel region PR1, a first transfer gat electrode 131a may be disposed on the first surface 100a of the semiconductor substrate 100. A first floating diffusion region 141 may be disposed in the semiconductor substrate 100 on one side of the first transfer gate electrode 131a.

On the second pixel region PR2, a second transfer gate electrode 131b may be disposed on the first surface 100a of the semiconductor substrate 100. A second floating diffusion region 145 may be disposed in the semiconductor substrate 100 on one side of the second transfer gate electrode 131b.

Portions of the first and second transfer gate electrodes 131a and 131b may be disposed in a trench formed by recessing the first surface 100a of the semiconductor substrate 100, and a gate dielectric layer may be interposed between the semiconductor substrate 100 and the first and second transfer gate electrodes 131a and 131b. In some embodiments, the first and second transfer gate electrodes 131a and 131b may be changed in terms of shape and position.

On the first pixel region PR1, the semiconductor substrate 100 may be provided therein with a first charge storage region 143a spaced apart from the first floating diffusion region 141. On the second pixel region PR2, the semiconductor substrate 100 may be provided therein with a second charge storage region 143b spaced apart from the second floating diffusion region 145. A portion of the pixel isolation structure PIS may be disposed between the first charge storage region 143a and the second charge storage region 143b.

The first and second floating diffusion regions 141 and 145 and the first and second charge storage regions 143a and 143b may be formed by doping impurities whose conductivity type is opposite to that of the semiconductor substrate 100. For example, the first and second floating diffusion regions 141 and 145 and the first and second charge storage regions 143a and 143b may be n-type impurity regions.

On the first pixel region PR1, a first switching gate electrode 133a may be disposed on the semiconductor substrate 100 between the first floating diffusion region 141 and the first charge storage region 143a.

On the second pixel region PR2, a second switching gate electrode 133b may be disposed on the semiconductor substrate 100 between the second floating diffusion region 145 and the second charge storage region 143b.

The first switching gate electrode 133a may overlap the first photoelectric conversion region PD1, and the second switching gate electrode 133b may overlap the second photoelectric conversion region PD2.

A first switching transistor controlled with a first switching signal applied to the first switching gate electrode 133a may prevent charges stored in the first floating diffusion region 141 from overflowing into the first charge storage region 143a.

A second switching transistor controlled with a second switching signal applied to the second switching gate electrode 133b may prevent charges stored in the second charge storage region 143b from overflowing into the second floating diffusion region 145.

According to some embodiments, a first well impurity region 121 may be provided in the semiconductor substrate 100 on the first pixel region PR1, and a second well impurity region 123 may be provided in the semiconductor substrate 100 on the second pixel region PR2. The first and second well impurity regions 121 and 123 may be formed by doping the semiconductor substrate 100 with impurities having the first conductivity type.

The first well impurity region 121 may partially overlap the first photoelectric conversion region PD1, and the second well impurity region 123 may partially overlap the second photoelectric conversion region PD2. The first well impurity region 121 may be provided in the semiconductor substrate 100 so as not to overlap the first floating diffusion region 141 when viewed in a vertical direction, and the second well impurity region 123 may be provided in the semiconductor substrate 100 so as not to overlap the second floating diffusion region 145 when viewed in a vertical direction (see, e.g., FIG. 3B).

The first well impurity region 121 may overlap the first switching gate electrode 133a and the first charge storage region 143a. The second well impurity region 123 may overlap the second switching gate electrode 133b and the second charge storage region 143b.

When viewed in vertical section, the first well impurity region 121 may be positioned between the first photoelectric conversion region PD1 and the first charge storage region 143a. The first well impurity region 121 may provide a potential barrier between the first photoelectric conversion region PD1 and the first charge storage region 143a. Therefore, in the first photoelectric conversion region PD1, charges may be prevented from overflowing into the first charge storage region 143a.

When viewed in vertical section, the second well impurity region 123 may be positioned between the second photoelectric conversion region PD2 and the second charge storage region 143b. The second well impurity region 123 may provide a potential barrier between the second photoelectric conversion region PD2 and the second charge storage region 143b. Therefore, in the second photoelectric conversion region PD2, charges may be prevented from overflowing into the second charge storage region 143b.

An interlayer dielectric layer 210 may be disposed on the first surface 100a of the semiconductor substrate 100, and may cover first and second transfer gate electrodes TG1 and TG2 (e.g., 131a and 131b) and pixel transistors (see RX, SF, SX, SW1, and SW2 of FIG. 2A) that constitute readout circuits. The interlayer dielectric layer 210 may include a plurality of dielectric layers. The interlayer dielectric layer 210 may include, for example, one or more of silicon oxide, silicon nitride, and silicon oxynitride.

The interlayer dielectric layer 210 may be provided therein with a wiring structure connected to the readout circuits. The wiring structure may include contact plugs CT1, CT2, CT3, and CT4 and metal lines ML1 and ML2. For example, a first contact plug CT1 may be coupled to the first floating diffusion region 141, a second contact plug CT2 may be coupled to the first charge storage region 143a, and a third contact plug CT3 may be coupled to the second charge storage region 143b. A fourth contact plug CT4 may be coupled to the second floating diffusion region 145.

The first contact plug CT1 may be connected to a second metal line ML2, and the second metal line ML2 may be electrically connected to a gate electrode of the source follower transistor SF. A first metal line ML1 may be connected to the drain terminal of the reset transistor RX.

The second and third contact plugs CT2 and CT3 may be electrically connected to each other through the second metal line ML2. For example, the first and second charge storage regions 133a and 133b of the first and second pixel regions PR1 and PR2 may be electrically connected to each other.

The fourth contact plug CT4 may be electrically connected to the capacitor C_{FD3} or the third switching transistor (see SW3 of FIG. 2B).

A planarization dielectric layer 310 may cover the second surface 100b of the semiconductor substrate 100. The planarization dielectric layer 310 may be formed of a transparent dielectric material and may include a plurality of layers. The planarization dielectric layer 310 may be formed of a dielectric material whose refractive index is different from that of the semiconductor substrate 100. The planarization dielectric layer 310 may include one or more of metal oxide and silicon oxide.

A grid structure 320 may be disposed on the planarization dielectric layer 310. Similar to the pixel isolation structure PIS, the grid structure 320 may have a grid or mesh shape when viewed in plan. When viewed in plan, the grid structure 320 may overlap the pixel isolation structure PIS. For example, the grid structure 320 may include first parts that extend in the first direction D1, and may include second parts that run across the first parts and extend in the second direction D2. The grid structure 320 may have a width substantially the same as or less than a minimum width of the pixel isolation structure PIS.

The grid structure 320 may include one or more of a conductive pattern and a low-refractive pattern. The conductive pattern may include a metallic material, such as titanium, tantalum, or tungsten. The low-refractive pattern may be formed of a material whose refractive index is less than that of the conductive pattern. The low-refractive pattern may be formed of an organic material and may have a refractive index of about 1.1 to about 1.3. For example, the grid structure 320 may be a polymer layer including silica nano-particles.

The planarization dielectric layer 310 may be provided thereon with a protection layer 330 having a substantially uniform thickness that covers a surface of the grid structure 320. The protection layer 330 may be a single or multiple layer including, for example, at least one selected from an aluminum oxide layer and a silicon carbon oxide layer.

A color filter 340 may be disposed to correspond to each unit pixel region UP. For example, the first and second pixel regions PR1 and PR2 of each unit pixel region UP may share one color filter 340. The first and second photoelectric conversion regions PD1 and PD2 of each unit pixel region UP may generate an electrical signal converted from light that passes through a single color filter 340.

The color filters 340 may fill spaces defined by the grid structure 320. In accordance with a unit pixel, the color filter 340 may include one of red, green, and blue color filters or one of magenta, cyan, and yellow color filters. Alternatively, one or some of the color filters 340 may include a white color filter or an infrared filter.

Microlenses 350 may be disposed on the color filters 340. The microlenses 350 may each have a convex shape with a certain curvature radius. The microlenses 350 may be formed of a light-transmitting resin. The color filters 340 may be provided thereon with the microlenses 350 that correspond to the first and second pixel regions PR1 and PR2.

As a sum of light-receiving areas of the first photoelectric conversion regions PD1 is greater than a sum of light-receiving areas of the second photoelectric conversion regions PD2, areas of the microlenses 350 disposed on the first photoelectric conversion regions PD1 may be greater than areas of the microlenses 350 disposed on the second photoelectric conversion regions PD2. Curvature radii of the microlenses 350 disposed on the first photoelectric conversion regions PD1 may be different from curvature radii of the microlenses 350 disposed on the second photoelectric conversion regions PD2.

FIG. 4 illustrates a plan view showing a unit pixel of an image sensor according to some embodiments of the disclosure. For brevity of description, those components substantially the same as those of the aforementioned embodiments are allocated the same reference numerals thereto, and explanations thereof will be simplified or omitted.

Referring to FIGS. 3A and 4, as discussed above, each unit pixel region UP may include a first pixel region PR1 and a second pixel region PR2. When viewed in plan, each of the first and second pixel regions PR1 and PR2 may be surrounded by the pixel isolation structure PIS.

The first pixel region PR1, or a first photoelectric conversion region PD1, may have an octagonal shape when viewed in plan. The second pixel region PR2, or a second photoelectric conversion region PD2, may have a tetragonal shape when viewed in plan, and may be adjacent to one of lateral surfaces of the first pixel region PR1. The planar shapes of the first and second pixel regions PR1 and PR2 are not limited thereto, and may be variously changed.

The device isolation layer 105 may define first, second, third, and fourth active sections ACT1, ACT2, ACT3, and ACT4 on the first and second pixel regions PR1 and PR2. For example, the first, third, and fourth active sections ACT1, ACT3, and ACT4 may be provided on the first pixel region PR1 on the first pixel region PR1, and the second active section ACT2 may be provided on the second pixel region PR2.

When viewed in plan, the first active section ACT1 may overlap the first photoelectric conversion region PD1, and the second active section ACT2 may overlap a second photoelectric conversion region PD2. The first and second active sections ACT1 and ACT2 may have different shapes and sizes on the first and second pixel regions PR1 and PR2. The third and fourth active sections ACT3 and ACT4 may overlap the first photoelectric conversion region PD1 and may be spaced apart from the first active section ACT1.

In some embodiments, no limitation is imposed on shape and the number of the first, second, third, and fourth active sections ACT1, ACT2, ACT3, and ACT4, and the shape and the number may be variously changed.

A first transfer gate electrode 131a may be disposed on the first active section ACT1. The first active section ACT1 may be provided thereon with a first switching gate electrode 133a spaced apart from the first transfer gate electrode 131a. A first floating diffusion region 141 may be provided in the first active section ACT1 between the first transfer gate electrode 131a and the first switching gate electrode 133a, and a first contact plug CT1 may be coupled to the first floating diffusion region 141. The first active section ACT1 may be provided therein with the first charge storage region 143a spaced apart from the first floating diffusion region 141, and a second contact plug CT2 may be coupled to the first charge storage region 133a.

A second gate electrode 131b may be disposed on the second active section ACT2. The second active section ACT2 may be provided thereon with a second switching gate electrode 133b and a third switching gate electrode 133c that are spaced apart from the second transfer gate electrode 131b. The third switching gate electrode 133c may be spaced apart from the second switching gate electrode 133b. Alternatively, the third switching gate electrode 133b may be omitted.

A second floating diffusion region 145 may be provided in the second active section ACT2 between the second transfer gate electrode 131a and the second switching gate electrode 133b. In addition, the second floating diffusion region 145 may be provided between the second switching gate electrode 133b and the third switching gate electrode 133c.

The second active section ACT2 may be provided therein with a second charge storage region 143b spaced apart from the second floating diffusion region 145, and a third contact plug CT3 may be coupled to the second charge storage region 133b. The third contact plug CT3 may be connected through a first metal line ML1 to the second contact plug CT2.

The second active section ACT2 may be provided therein with a source/drain impurity region that is spaced apart from the second floating diffusion region 145 and is adjacent to the third switching gate electrode 133c, and a fourth contact plug CT4 may be provided in the source/drain impurity region. The fourth contact plug CT4 may be electrically connected to a capacitor C_{FD3}.

A source follower gate electrode 137 and a selection gate electrode 139 may be disposed on the third active section ACT3 of the first pixel region PR1, and a reset gate electrode 135 may be disposed on the fourth active section ACT4 of the first pixel region PR1.

First and second impurity regions may be provided in the fourth active section ACT4 on opposite sides of the reset gate electrode 135, a fifth contact plug CT5 may be coupled to the first impurity region, and a seventh contact plug CT7 may be coupled to the second impurity region. The fifth contact plug CT5 may be electrically connected in common to the second and third contact plugs CT2 and CT3 through the first metal line ML1.

A sixth contact plug CT6 may be coupled to the source follower gate electrode 137. The sixth contact plug CT6 may be electrically connected through a second metal line ML2 to the first contact plug CT1 on the first active section ACT1.

A third impurity region may be provided in the third active section ACT3 on one side of the source follower gate electrode 137, and the pixel power voltage V_{DD} may be applied to the third impurity region. A fourth impurity region may be provided in the third active section ACT3 on one side of the selection gate electrode 139, and an eighth contact plug CT8 may be coupled to the fourth impurity region. The eighth contact plug CT8 may be connected to an output line.

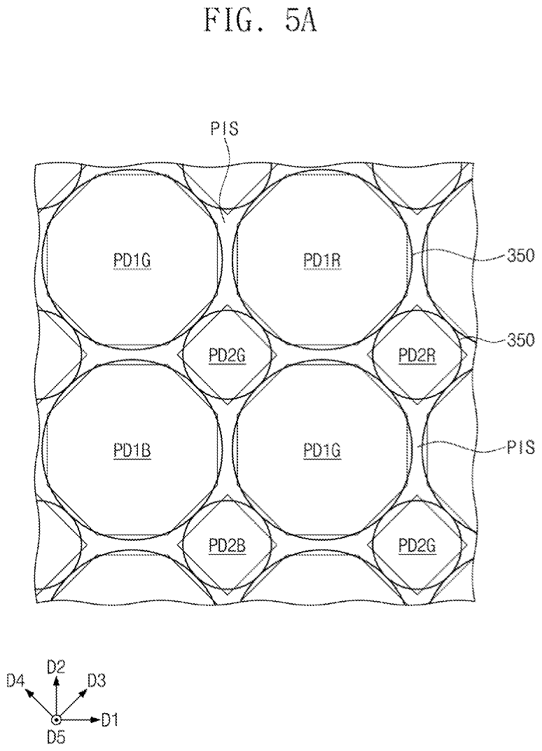

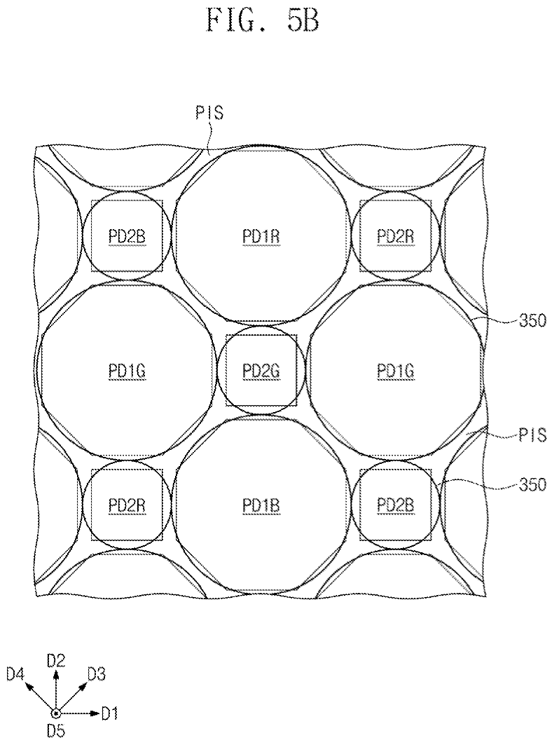

FIGS. 5A and 5B illustrate cross-sectional views showing an image sensor according to some embodiments of the disclosure. For brevity of description, those components substantially the same as those of the aforementioned embodiments are allocated the same reference numerals thereto, and explanations thereof will be simplified or omitted.

Referring to FIG. 3A or 3B and FIGS. 5A and 5B, an image sensor may include a plurality of unit pixel regions UP, and as discussed above, each unit pixel region UP may include a first pixel region PR1 and a second pixel region PR2. The plurality of unit pixel regions UP may constitute an array.

First photoelectric conversion regions PD1R, PD1G, and PD1B, or the first pixel regions PR1, may be two-dimensionally arranged in rows and columns. The rows may be parallel to a first direction D1. The columns may be parallel to a second direction D2. The first photoelectric conversion regions PD1R, PD1G, and PD1B may be arranged in a first diagonal direction D3. The first photoelectric conversion regions PD1R, PD1G, and PD1B may be arranged in a second diagonal direction D4.

In this description, the first direction D1 may be parallel to a first surface 100a of a semiconductor substrate 100. The second direction D2 may be parallel to the first surface 100a of the semiconductor substrate 100 and may be different from the first direction D1. For example, the second direction D2 may be substantially orthogonal to the first direction D1.

The first diagonal direction D3 may be parallel to the first surface 100a of the semiconductor substrate 100, and may intersect the first direction D1 and the second direction D2. For example, the first diagonal direction D3 and the first direction D1 may make an angle of about 45 degrees with each other. The first diagonal direction D3 and the second direction D2 may make an angle of about 45 degrees with each other.

The second diagonal direction D4 may be parallel to the first surface 100a, and may intersect the first direction D1, the second direction D2, and the first diagonal direction D3. For example, the second diagonal direction D4 may be substantially orthogonal to the first diagonal direction D3.

A third direction D5 may intersect the first direction D1, the second direction D2, the first diagonal direction D3, and the second diagonal direction D4. For example, the third direction D5 may be substantially perpendicular to the first surface 100a of the semiconductor substrate 100.

Each of the first photoelectric conversion regions PD1R, PD1G, and PD1B may have an octagonal shape when viewed in plan. Each of the first photoelectric conversion regions PD1R, PD1G, and PD1B may have a first width in the first direction D1. The first width may be a width measured on the first surface 100a of the semiconductor substrate 100. In addition, the first width may correspond to an interval between portions of a pixel isolation structure PIS.

When viewed in plan, each of a plurality of second photoelectric conversion regions PD2R, PD2G, and PD2B, or each of the second pixel regions PR2, may be surrounded by neighboring four first photoelectric conversion regions PD1R, PD1G, and PD1B. When viewed in plan, the second photoelectric conversion regions PD2R, PD2G, and PD2B may be two-dimensionally arranged along the first direction D1 and the second direction D2.

Referring to FIG. 5A, the first photoelectric conversion regions PD1R, PD1G, and PD1B and the second photoelectric conversion regions PD2R, PD2G, and PD2B may be alternately disposed along the first diagonal direction D3 and the second diagonal direction D4. When viewed in the first diagonal direction D3 and the second diagonal direction D4, each of the second photoelectric conversion regions PD2R, PD2G, and PD3B may be disposed between the first photoelectric conversion regions PD1R, PD1G, and PD1B.

Referring to FIG. 5B, the first photoelectric conversion regions PD1R, PD1G, and PD1B and the second photoelectric conversion regions PD2R, PD2G, and PD2B may be alternately disposed along the first direction D1. When viewed in the first direction D1 and the second direction D2, each of the second photoelectric conversion regions PD2R, PD2G, and PD2B may be disposed between the first photoelectric conversion regions PD1R, PD1G, and PD1B.

Each of the second photoelectric conversion regions PD2R, PD2G, and PD2B may have a tetragonal shape when viewed in plan. The sizes of the second photoelectric conversion regions PD2R, PD2G, and PD2B may be smaller than those of the first photoelectric conversion regions PD1R, PD1G, and PD1B. In this sense, light-receiving areas of the second photoelectric conversion regions PD2R, PD2G, and PD2B may be smaller than those of the first photoelectric conversion regions PD1R, PD1G, and PD1B.

Each of the second photoelectric conversion regions PD2R, PD2G, and PD2B may have a second width in the first direction D1 smaller than the first width in the first direction D1 of the first photoelectric conversion regions PD1R, PD1G, and PD1B. In this description, widths of two components may be compared with each other in the same direction at the same level.

According to some embodiments, an arrangement of unit pixels may be highly integrated due to adjustment of the planar shapes and the first widths of the first photoelectric conversion regions PD1R, PD1G, and PD1B and due to adjustment of the planar shapes and the second widths of the second photoelectric conversion regions PD2R, PD2G, and PD2B. Therefore, the image sensor may improve in optical properties.

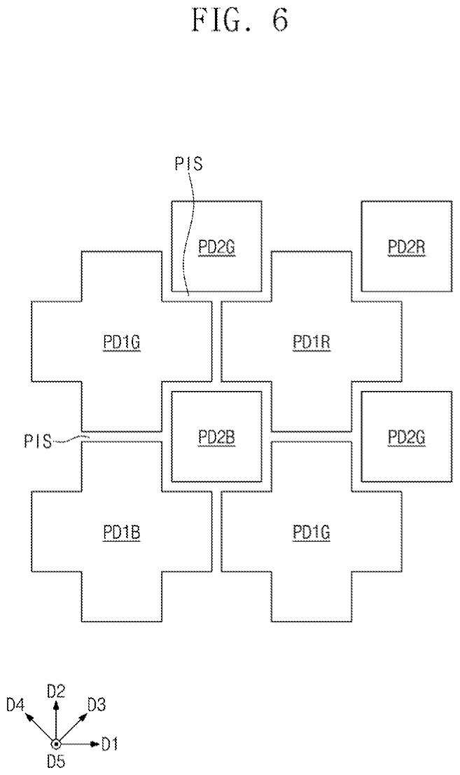

FIG. 6 illustrates a plan view showing an image sensor according to some embodiments of the disclosure. For brevity of description, those components substantially the same as those of the aforementioned embodiments are allocated the same reference numerals thereto, and explanations thereof will be simplified or omitted.

According to the embodiment shown in FIG. 6, as discussed above, each unit pixel region UP may include a first pixel region PR1 and a second pixel region PR2. When viewed in plan, each of the first and second pixel regions PR1 and PR2 may be surrounded by a pixel isolation structure PIS.

The first pixel region PR1, or a first photoelectric conversion region PD1R, PD1G, or PD1B, may have a cross shape when viewed in plan. The second pixel region PR2, or a second photoelectric conversion region PD2R, PD2G, or PD2B, may have a tetragonal shape when viewed in plan, and may be surrounded by four first photoelectric conversion regions PD1R, PD1G, and PD1B.

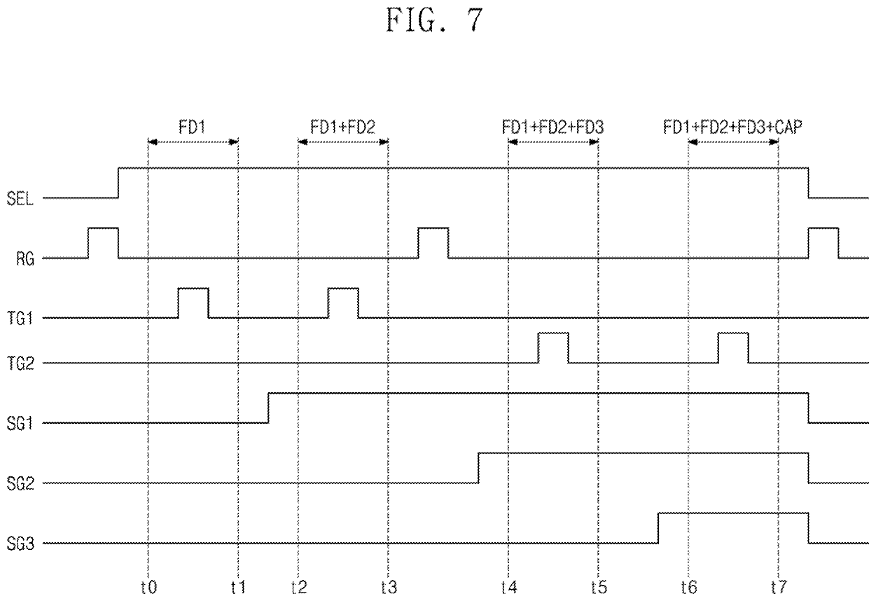

FIG. 7 illustrates a timing diagram showing an operation of the image sensor depicted in FIG. 2B.

Referring to FIGS. 2B and 7, the image sensor may operate in such a way that the reset signal RG is activated to turn on the reset transistor RX. Therefore, the pixel power voltage V_{DD} may be applied to the first charge detection node FD1 (or the first floating diffusion region) such that charges may be exhausted from the first charge detection node FD1 (or the first floating diffusion region), with the result that the first charge detection node FD1 may be reset or initialized.

When the reset signal RG is activated, the first and second switching signals SG1 and SG2 may be activated to also provide the second and third charge detection nodes FD2 and FD3 with the pixel power voltage V_{DD}. Thus, the second and third charge detection nodes FD2 and FD3 may also be reset.

The reset signal RG may be inactivated to turn off the reset transistor RX. The first, second, and third charge detection nodes FD1, FD2, and FD3 may be in a state capable of accumulating charges.

Immediately after the reset transistor RX is turned off, the selection signal SEL may be activated to turn on the selection transistor SX. When the selection transistor SX is turned on, the output line V_{OUT} may output pixel signals.

At a time of t0, a first reset signal may be output which is in proportion to a potential of the first charge detection node FD1.

After the first reset signal is read out, a first transfer signal TG1 may be activated to turn on the first transfer transistor TX1. Thus, charges accumulated in the first photoelectric conversion element PD1 in a first conversion gain mode may be transferred to the first charge detection node FD1.

The first transfer signal TG1 may be inactivated to turn off the first transfer transistor TX1, and at a time of t1, a first pixel signal may be output which is in proportion to an amount of photo-charges accumulated in the first photoelectric conversion element PD1 in the first conversion gain mode.

After the first pixel signal is output, the first switching signal SG1 may be activated to turn on the first switching transistor SW1. Therefore, the unit pixel P may operate in a second conversion gain mode having a second conversion gain greater than a first conversion gain.

As the first switching transistor SW1 is turned on, a capacitance of the first charge detection node FD1 may increase to a sum of capacitances of the first and second charge detection nodes FD1 and FD2.

After the first switching transistor SW1 is turned on, at a time of t2, a second reset signal may be output which is in proportion to a potential of the first and second charge detection nodes FD1 and FD2.

After the second reset signal is read out, the first transfer signal TG1 may be activated to turn on again the first transfer transistor TX1. Thus, charges accumulated in the first photoelectric conversion element PD1 in the second conversion gain mode may be transferred to the first and second charge detection nodes FD1 and FD2.

The first transfer signal TG1 may be inactivated to turn off the first transfer transistor TX1, and at a time of t3, a second pixel signal may be output which is in proportion to an amount of photo-charges accumulated in the first photoelectric conversion element PD1 in the second conversion gain mode. The second pixel signal may be in proportion to an amount of charges accumulated in the first and second charge detection nodes FD1 and FD2.

The reset signal RG may be activated to turn on the reset transistor RX. Thus, charges may be exhausted from the first and second charge detection nodes FD1 and FD2, such that the first and second charge detection nodes FD1 and FD2 may be reset.

After the first and second charge detection nodes FD1 and FD2 are reset, the second switching signal SG2 may be activated to turn on the second switching transistor SW2. Therefore, the unit pixel P may operate in a third conversion gain mode having a third conversion gain greater than the second conversion gain.

As the first and second switching transistors SW1 and SW2 are turned on, a capacitance of the first charge detection node FD1 may increase to a sum of capacitances of the first, second, and third charge detection nodes FD1, FD2, and FD3.

After the second switching transistor SW2 is turned on, at a time of t4, a third reset signal may be output which is in proportion to a potential of the first, second, and third charge detection nodes FD1, FD2, and FD3.

After the third reset signal is read out, a second transfer signal TG2 may be activated to turn on the second transfer transistor TX2. Thus, charges accumulated in the second photoelectric conversion element PD2 in the third conversion gain mode may be transferred to the first, second, and third charge detection nodes FD1, FD2, and FD3.

The second transfer signal TG2 may be inactivated to turn off the second transfer transistor TX2, and at a time of t5, a third pixel signal may be output which is in proportion to an amount of photo-charges accumulated in the second photoelectric conversion element PD2 in the third conversion gain mode. The third pixel signal may be in proportion to an amount of charges accumulated in the first, second, and third charge detection nodes FD1, FD2, and FD3.

After the third pixel signal is output, the third switching signal SG3 may be activated to turn on the third switching transistor SW3. Therefore, the unit pixel P may operate in a fourth conversion gain mode having a fourth conversion gain greater than the third conversion gain.

As the third switching transistor SW3 is turned on, a capacitance of the first charge detection node FD1 may increase to a sum of capacitances of the first, second, and third charge detection nodes FD1, FD2, and FD3.

After the third switching transistor SW3 is turned on, at a time of t6, a fourth reset signal may be output which is in proportion to a potential of the first, second, and third charge detection nodes FD1, FD2, and FD3 and the capacitor C_{FD3}.

After the fourth reset signal is read out, the second transfer signal TG2 may be re-activated to turn on the second transfer transistor TX2. Thus, charges accumulated in the second photoelectric conversion element PD2 in the fourth conversion gain mode may be transferred to the first, second, and third charge detection nodes FD1, FD2, and FD3 and the capacitor C_{FD3}.

The second transfer signal TG2 may be inactivated to turn off the second transfer transistor TX2, and at a time of t7, a fourth pixel signal may be output which is in proportion to an amount of photo-charges accumulated in the second photoelectric conversion element PD2 in the fourth conversion gain mode. The fourth pixel signal may be in proportion to an amount of charges accumulated in the first, second, and third charge detection nodes FD1, FD2, and FD3 and the capacitor C_{FD3}.

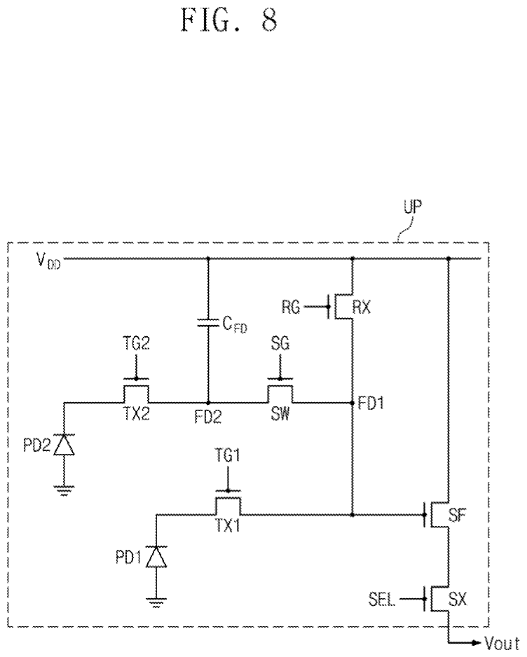

FIG. 8 illustrates a circuit diagram showing a unit pixel of a pixel array according to some embodiments of the disclosure.

Different from the unit pixel region UP discussed with reference to FIG. 2A, a unit pixel region UP depicted in FIG. 8 may include one switching transistor SW, and other features may be substantially the same as those illustrated in FIG. 2A. For brevity of description, those components substantially the same as those of the aforementioned embodiments are allocated the same reference numerals thereto, and explanations thereof will be simplified or omitted.

Referring to FIG. 8, the unit pixel region UP may include first and second photoelectric conversion elements PD1 and PD2, first and second charge transfer transistors TX1 and TX2, and pixel transistors. In this disclosure, the pixel transistors may include a switching transistor SW (or a switching element), a capacitor C_{FD} (or a charge storage element), a reset transistor RX, a source follower transistor SF, and a selection transistor SX.

The first transfer transistor TX1 may be configured to transfer the electric charges, which are accumulated in the first photoelectric conversion element PD1, to a first charge detection node FD1 (i.e., first floating diffusion region). The second transfer transistor TX2 be configured to transfer the electric charges, which are accumulated in the second photoelectric conversion element PD2, to a third charge detection node FD3 (or a third floating diffusion region). The first and second transfer transistors TX1 and TX2 may be controlled by first and second transfer signals TG1 and TG2.

The first charge detection node FD1 may receive and accumulate charges generated from the first photoelectric conversion element PD1. The source follower transistor SF may be controlled by an amount of photo-charges accumulated in the first charge detection node FD1.

The switching transistor SW may be connected between the first charge detection node FD1 and the second charge detection node FD2. In response to a switching signal SG, the switching transistor SW may change a capacitance of the first charge detection node FD1, thereby changing a conversion gain of the unit pixel region UP.

The capacitor C_{FD} may be connected between the second charge detection node FD2 and a pixel power voltage V_{DD}. The capacitor C_{FD} may be, for example, a metal-oxide-semiconductor (MOS) capacitor, a metal-insulator-semiconductor (MIS) capacitor, or a metal-insulator-metal (MIM) capacitor. When the second transfer transistor TX2 is turned on, charges generated from the second photoelectric conversion element PD2 may be accumulated or stored in the capacitor C_{FD}.

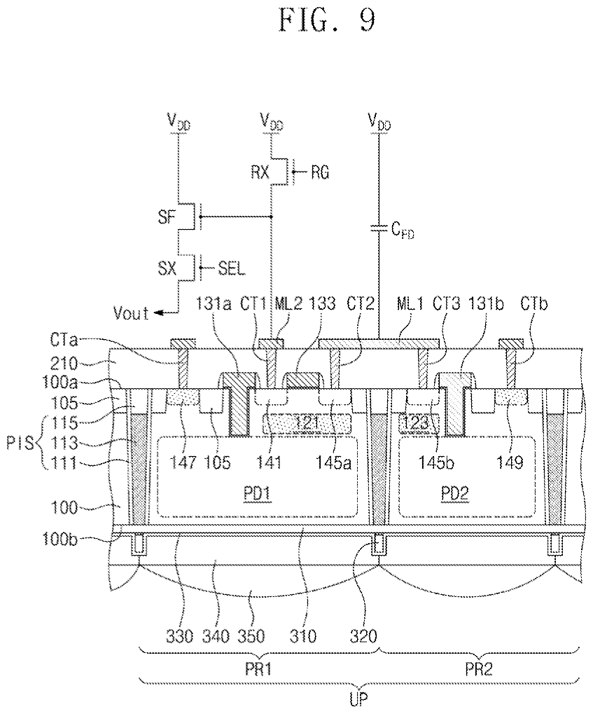

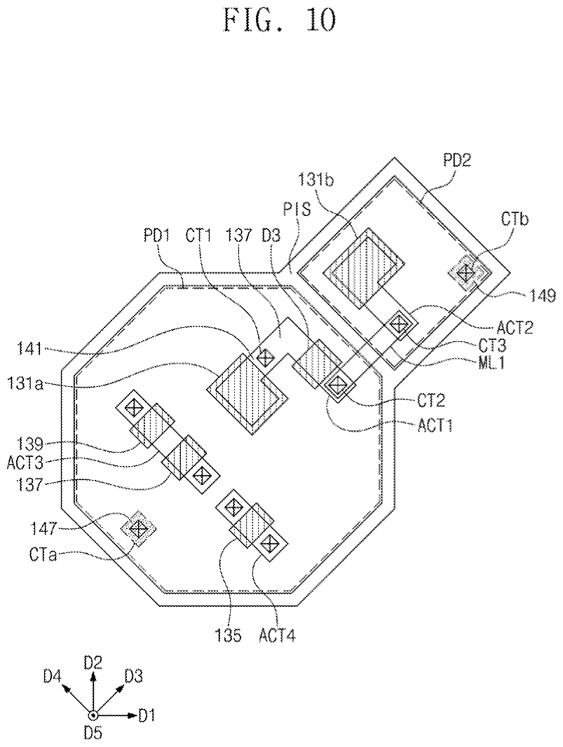

FIG. 9 illustrates a cross-sectional view showing an image sensor according to some embodiments of the disclosure. FIG. 10 illustrates a plan view showing a unit pixel of the image sensor depicted in FIG. 9. For brevity of description, those components substantially the same as those of the aforementioned embodiments are allocated the same reference numerals thereto, and explanations thereof will be simplified or omitted.

Referring to FIGS. 9 and 10, as discussed above, each unit pixel region UP may include a first pixel region PR1 and a second pixel region PR2.

Each of the first and second pixel regions PR1 and PR2 may be defined by a pixel isolation structure PIS provided in a semiconductor substrate 100. When viewed in plan, each of the first and second pixel regions PR1 and PR2 may be surrounded by the pixel isolation structure PIS.

As discussed above, the first pixel region PR1, or a first photoelectric conversion region PD1, may have an octagonal shape when viewed in plan. The second pixel region PR2, or a second photoelectric conversion region PD2, may have a tetragonal shape when viewed in plan, and may be adjacent to one of lateral surfaces of the first pixel region PR1. The planar shapes of the first and second pixel regions PR1 and PR2 are not limited thereto, and may be variously changed.

On the first pixel region PR1, the first photoelectric conversion region PD1 may be provided in the semiconductor substrate 100. On the second pixel region PR2, the second photoelectric conversion region PD2 may be provided in the semiconductor substrate 100.

Each of the first and second photoelectric conversion regions PD1 and PD2 may be doped with impurities having a second conductivity type (e.g., n-type) opposite to a first conductivity type of the semiconductor substrate 100.

When viewed in plan, each of the first and second photoelectric conversions regions PD1 and PD2 may be surrounded by the pixel isolation structure PIS. Therefore, photo-charges accumulated in the first and second photoelectric conversion regions PD1 and PD2 may be prevented from overflowing into adjacent first and second photoelectric conversion regions PD1 and PD2.

On each of the first and second pixel regions PR1 and PR2, a device isolation layer 105 may define at least one active section on a first surface 100a of the semiconductor substrate 100. For example, the device isolation layer 105 may define first, second, third, and fourth active sections ACT1, ACT2, ACT3, and ACT4 on the first and second pixel regions PR1 and PR2. The first, second, and third active sections ACT1, ACT2, and ACT3 may be provided on the first pixel region PR1 of each unit pixel region UP, and the second active section ACT2 may be provided on the second pixel region PR2 of each unit pixel region UP.

An arrangement and shape of the first to fourth active sections ACT1 to ACT4 may be variously changed in accordance with embodiments.

On the first pixel region PR1, a first transfer gate electrode 131a may be disposed on the first active section ACT1, and a first floating diffusion region 141 may be provided in the first active section ACT1 of the semiconductor substrate 100 on one side of the first transfer gate electrode 131a.

On the second pixel region PR2, a second transfer gate electrode 131b may be disposed on the second active section ACT2.

Second floating diffusion regions 145a and 145b may be provided in the semiconductor substrate 100 on the first and second pixel regions PR1 and PR2. The second floating diffusion regions 145a and 145b may be spaced apart from each other across a portion of the pixel isolation structure PIS.

The second floating diffusion region 145a of the first pixel region PR1 may be provided in the first active section ACT1 of the semiconductor substrate 100. The second floating diffusion region 145b of the second pixel region PR2 may be provided in the second active section ACT2 of the semiconductor substrate 100 on one side of the second transfer gate electrode 131b.

On the first pixel region PR1, a switching gate electrode 133 may be disposed on the semiconductor substrate 100 between the first floating diffusion region 141 and the second floating diffusion region 145a.

A source follower gate electrode 137 and a selection gate electrode 139 may be disposed on the third active section ACT3 of the first pixel region PR1, and a reset gate electrode 135 may be disposed on the fourth active section ACT4 on the first pixel region PR1.

In addition, as discussed above, a first well impurity region 121 may be provided in the semiconductor substrate 100 on the first pixel region PR1, and a second well impurity region 123 may be provided in the semiconductor substrate 100 on the second pixel region PR2.

The first well impurity region 121 may partially overlap the first photoelectric conversion region PD1, and the second well impurity region 123 may partially overlap the second photoelectric conversion region PD2.

When viewed in vertical section, the first well impurity region 121 may be positioned between the first photoelectric conversion region PD1 and the second floating diffusion region 145a on the first pixel region PR1. The first well impurity region 121 may provide a potential barrier between the first photoelectric conversion region PD1 and the second floating diffusion region 145a on the second pixel region PR2. Therefore, charges may be prevented from overflowing into the second floating diffusion region 145a from the first photoelectric conversion region PD1.

When viewed in vertical section, the second well impurity region 123 may be positioned between the second photoelectric conversion region PD2 and the second floating diffusion region 145b. The second well impurity region 123 may provide a potential barrier between the second photoelectric conversion region PD2 and the second floating diffusion region 145b. Therefore, charges may be prevented from overflowing into the second floating diffusion region 145b from the second photoelectric conversion region PD2.

According to some embodiments, a first pick-up impurity region 147 may be provided in the semiconductor substrate 100 on the first pixel region PR1, and a second pick-up impurity region 149 may be provided in the semiconductor substrate 100 on the second pixel region PR2. The first and second pick-up impurity regions 147 and 149 may be formed by doping the semiconductor substrate 100 having a first conductivity type with impurities having the first conductivity type.

A first bias contact plug CTa may be coupled to the first pick-up impurity region 147, and a second bias contact plug CTb may be coupled to the second pick-up impurity region 149. When an image sensor is operated, a ground voltage or a negative voltage may be applied to the first and second pick-up impurity regions 147 and 149.

A first contact plug CT1 may be coupled to the first floating diffusion region 141. A second contact plug CT2 may be coupled to the second floating diffusion region 145a on the first pixel region PR1, and a third contact plug CT3 may be coupled to the second floating diffusion region 145b on the second pixel region PR2.

The second floating diffusion regions 145a and 145b on the first and second pixel regions PR1 and PR2 may be electrically connected to each other through the second and third contact plugs CT2 and CT3 and a first metal line ML1. The first metal line ML1 may be electrically connected to the capacitor C_{FD}.

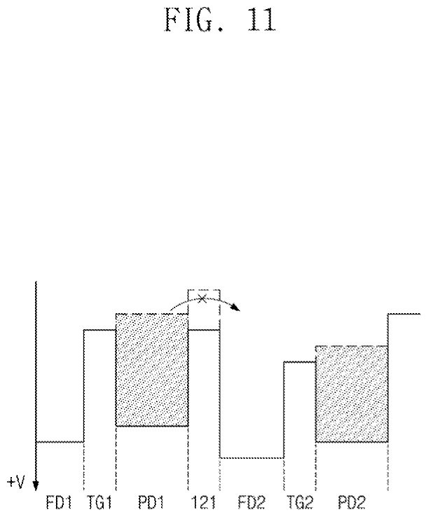

FIG. 11 illustrates a potential diagram of the image sensor depicted in FIG. 10.

Referring to FIGS. 8, 9, 10, and 11, in an integration mode of the second photoelectric conversion region PD2, the second transfer transistor TX2 and the switching transistor SW may be turned on such that charges generated from the second photoelectric conversion region PD2 may be transferred to and stored in the second charge detection node FD2 (or the second floating diffusion regions 145a and 145b).

When an image sensor is irradiated with light having high illumination, during output of a pixel signal proportional to an amount of photo-charges stored in the second photoelectric conversion element PD2, charges generated from the first photoelectric conversion region PD1 may overcome a potential barrier of the first well impurity region 121 to overflow into the second charge detection node FD2 (or the second floating diffusion regions 145a and 145b). The overflowed photo-charges may distort the pixel signal that is output from the second photoelectric conversion region PD2.

Therefore, according to some embodiments, when the second transfer transistor TX2 and the switching transistor SW are turned on, a negative bias may be applied to the semiconductor substrate 100 on the first pixel region PR1, and a ground voltage may be applied to the semiconductor substrate 100 on the second pixel region PR2. For example, a negative voltage may be applied to the first pick-up impurity region 147 on the first pixel region PR1, and a ground voltage may be applied to the second pick-up impurity region 149 on the second pixel region PR2. Thus, a potential barrier of the first well impurity region 121 may be increased as indicated by a dotted line depicted in FIG. 11. Accordingly, a blooming margin may be secured in the first photoelectric conversion region PD1 while a pixel signal is read in the second photoelectric conversion region PD2.

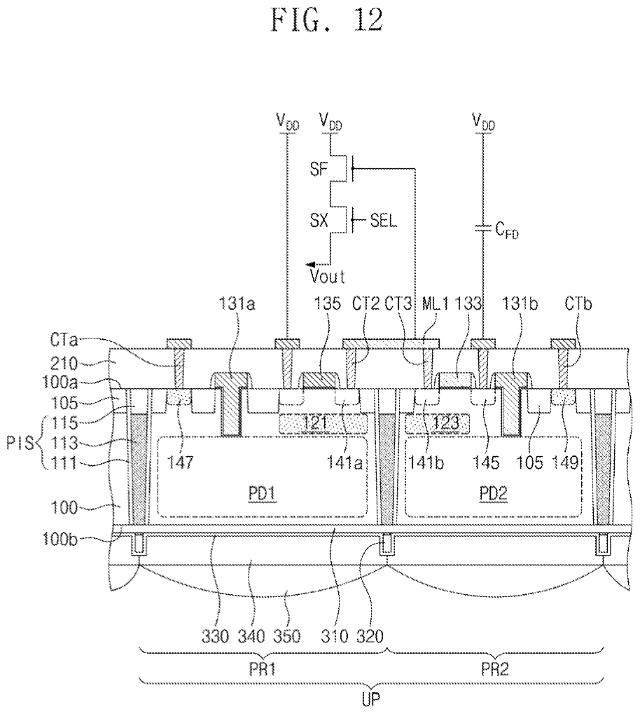

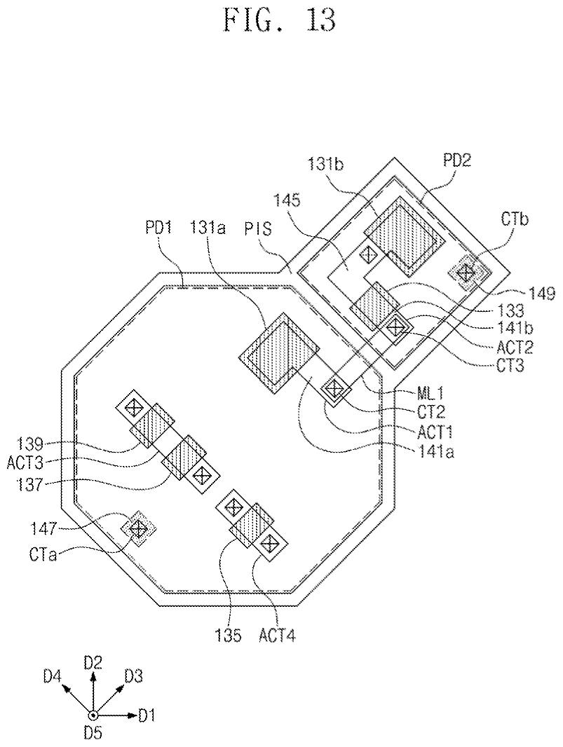

FIG. 12 illustrates a cross-sectional view showing an image sensor according to some embodiments of the disclosure. FIG. 13 illustrates a plan view showing a unit pixel of the image sensor depicted in FIG. 12. For brevity of the description, those components substantially the same as those of the embodiments discussed with reference to FIGS. 9 and 10 are allocated the same reference numerals thereto, and explanations thereof will be simplified or omitted.

Referring to FIGS. 12 and 13, a unit pixel region UP may include first and second pixel regions PR1 and PR2.

The first pixel region PR1 may be provided thereon with a first transfer gate electrode 131a, a reset gate electrode 135, a source follower gate electrode 137, and a selection gate electrode 139.

The second pixel region PR2 may be provided thereon with a second transfer gate electrode 131b and a switching gate electrode 133. The switching gate electrode 133 may be disposed between a first floating diffusion region 141b and a second floating diffusion region 145 of the second pixel region PR2.

First floating diffusion regions 141a and 141b may be provided in the semiconductor substrate 100 on the first and second pixel regions PR1 and PR2. The first floating diffusion regions 141a and 141b may be spaced apart from each other across a portion of a pixel isolation structure PIS.

The first floating diffusion regions 141a and 141b on the first and second pixel regions PR1 and PR2 may be electrically connected to each other through second and third contact plugs CT2 and CT3 and a first metal line ML1. The first metal line ML1 may be electrically connected to the gate electrode 137 of the source follower transistor SF.

In addition, as discussed above, a first well impurity region 121 may be provided in the semiconductor substrate 100 on the first pixel region PR1, and a second well impurity region 123 may be provided in the semiconductor substrate 100 on the second pixel region PR2. The first and second well impurity regions 121 and 123 may include impurities having a first conductivity type the same as that of the semiconductor substrate 100.

When viewed in vertical section, the first well impurity region 121 may be positioned between the first photoelectric conversion region PD1 and the first floating diffusion region 141a on the first pixel region PR1. When viewed in vertical section, the second well impurity region 123 may be positioned between the second photoelectric conversion region PD2 and the first floating diffusion region 141b on the second pixel region PR2.

In addition, a first pick-up impurity region 147 may be provided in the semiconductor substrate 100 on the first pixel region PR1, and a second pick-up impurity region 149 may be provided in the semiconductor substrate 100 on the second pixel region PR2.

When an image sensor is operated, a ground voltage or a negative voltage may be applied through first and second bias contact plugs CTa and CTb to the first and second pick-up impurity regions 147 and 149.

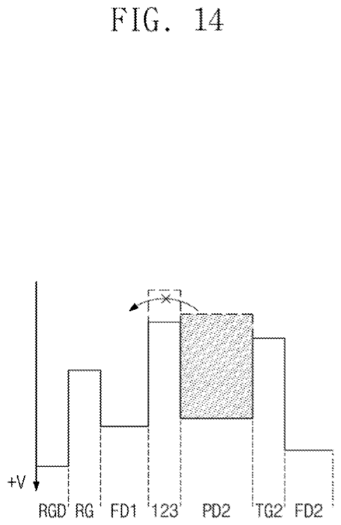

FIG. 14 illustrates a potential diagram of the image sensor depicted in FIGS. 12 and 13.

Referring to FIGS. 8, 12, 13, and 14, during output of a pixel signal proportional to an amount of photo-charges stored in the first photoelectric conversion element PD1, charges generated from the second photoelectric conversion region PD2 may overcome a potential barrier of the second well impurity region 123 to overflow into the first charge detection node FD1 (or the first floating diffusion regions 141a and 141b). Therefore, when the first transfer transistor TX1 and the switching transistor SW are turned on, a negative bias may be applied to the semiconductor substrate 100 on the second pixel region PR2, and a ground voltage may be applied to the semiconductor substrate 100 on the first pixel region PR1. For example, a ground voltage may be applied to the first pick-up impurity region 147 on the first pixel region PR1, and a negative voltage may be applied to the second pick-up impurity region 149 on the second pixel region PR2. Thus, a potential barrier of the second well impurity region 123 may be increased as indicated by a dotted line depicted in FIG. 14. Accordingly, there may be a reduction in overflow of charges generated from the second photoelectric conversion region PD2 into the first charge detection node FD1 (or the first floating diffusion regions 141a and 141b). In FIG. 14, symbol RGD may correspond to a drain region of the reset transistor RX.

According to some embodiments, it may be possible to reduce a blooming phenomenon between the first and second photoelectric conversion regions PD1 and PD2 due to a difference in potential between the first and second photoelectric conversion regions PD1 and PD2.

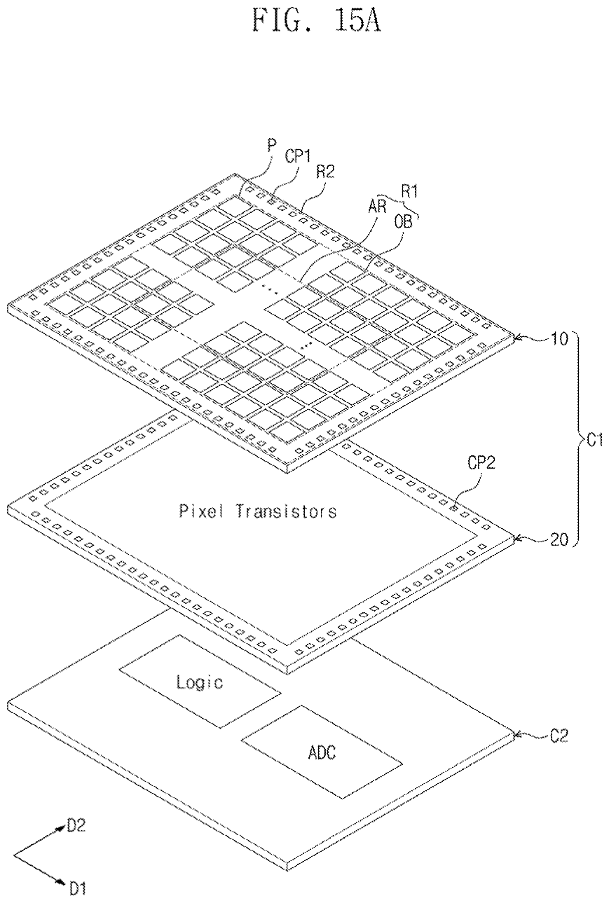

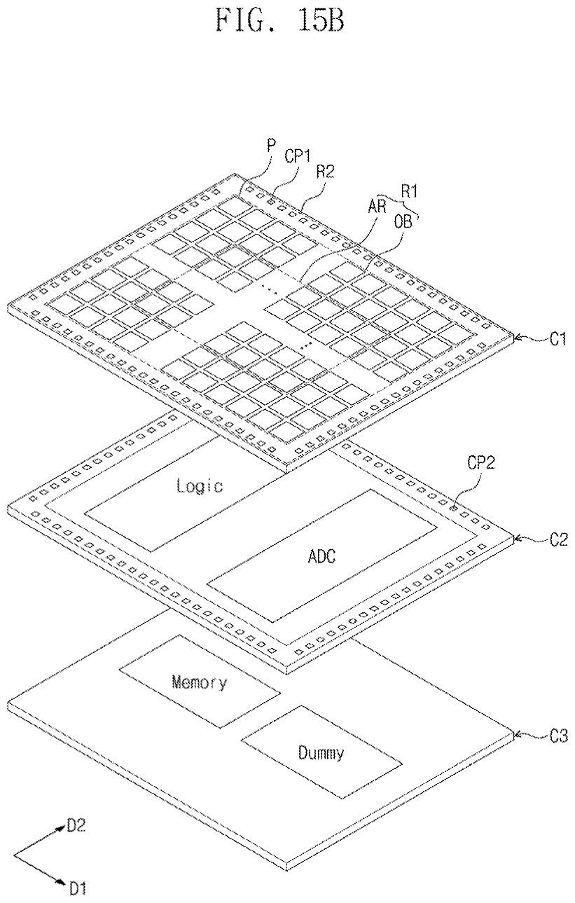

FIGS. 15A and 15B illustrate simplified perspective views showing an image sensor according to some embodiments of the disclosure.

Referring to FIG. 15A, an image sensor may include a sensor chip C1 and a logic chip C2.

The sensor chip C1 may convert images of external objects into electrical signals or data signals. The sensor chip C1 may include a pixel array (see 1 of FIG. 1) discussed above with reference to FIG. 1. For example, the sensor chip C1 may include a plurality of unit pixels, and as discussed above with reference to FIGS. 2A and 2B, each of the unit pixels may include photoelectric conversion elements and pixel transistors.

The sensor chip C1 may include a pixel array region R1 and a pad region R2. The pixel array region R1 may include a plurality of unit pixels that are two-dimensionally arranged along a first direction D1 and a second direction D2 that intersect each other. Each unit pixel of the pixel array region R1 may output an electrical signal generated from incident light.

The pixel array region R1 may include a light-receiving region AR and a light-shielding region OB. When viewed in plan, a light-shielding region OB may surround the light-receiving region AR. For example, when viewed in plan, the light-shielding region OB may be disposed on an upside, downside, left-side, and right-side of the light-receiving region AR. The light-shielding region OB may include reference pixels on which no light is incident, and an amount of charges sensed in the unit pixels of the light-receiving region AR may be compared with a reference amount of charges occurring at reference pixels, which may result in obtaining magnitudes of electrical signals sensed in the unit pixels.

The pad region R2 may be provided thereon with a plurality of conductive pads CP1 used to input and output control signals and photoelectric signals. For easy connection with external devices, the pad region R2 may surround the pixel array region R1, in a plan view. The conductive pads CP1 may allow an external device to receive electrical signals generated from the unit pixels.

The sensor chip C1 may include a photoelectric conversion circuit layer 10, a pixel circuit layer 20, and an optical transmission layer. When viewed in vertical section, the photoelectric conversion circuit layer 10 may be disposed between the pixel circuit layer 20 and the optical transmission layer. The photoelectric conversion circuit layer 10 may include transfer transistors and photoelectric conversion elements of a plurality of unit pixels discussed above with reference to FIGS. 3A and 3B. In addition, the pixel circuit layer 20 may include pixel transistors discussed above with reference to FIGS. 2A and 2B.

The pixel circuit layer 20 may be adjacent to the logic chip C2. The pixel circuit layer 20 may include conductive pads CP2 that correspond to the conductive pads CP1 of the sensor chip C1. The conductive pads CP1 of the sensor chip C1 may be bonded directly, or via through electrodes such as through silicon vias (TSV), to the conductive pads CP2 of the pixel circuit layer 20.

The logic chip C2 may include logic circuits (see 2, 3, 4, 5, 6, 7, and 8 of FIG. 1), a power circuit, an input/output interface, and/or an image signal processor. For example, the logic chip C2 may include components other than the pixel array 1 of the image sensor depicted in FIG. 1.

The logic chip C2 may include a logic pad region that corresponds to the pad region R2 of the sensor chip C1. The logic pad region may be provided thereon with a plurality of conductive pads used to input and output control signals. The conductive pads CP1 of the sensor chip C1 may be electrically connected to the conductive pads of the logic chip C2. The logic chip C2 may be bonded to the sensor chip C1 so as to adjoin the pixel circuit layer 20 of the sensor chip C1.

Referring to FIG. 15B, an image sensor may include a sensor chip C1, a logic chip C2, and a memory chip C3, and the sensor chip C1 may include a plurality of unit pixels and pixel circuits discussed above with reference to FIGS. 2A and 2B.

The logic chip C2 may include logic circuits (see 2, 3, 4, 5, 6, 7, and 8 of FIG. 1). The pixel circuit layer 20 of the logic chip C2 may include a logic pad region that corresponds to a pad region R2 of the sensor chip C1, and conductive pads CP2 may be disposed on the logic pad region. Conductive pads CP1 of the sensor chip C1 may be electrically connected to the conductive pads CP2 of the logic chip C2.

The memory chip C3 may include a main memory chip and a dummy memory chip, and conductive pads of the memory chip C3 may be connected via through electrodes to the conductive pads CP2 of the logic chip C2.

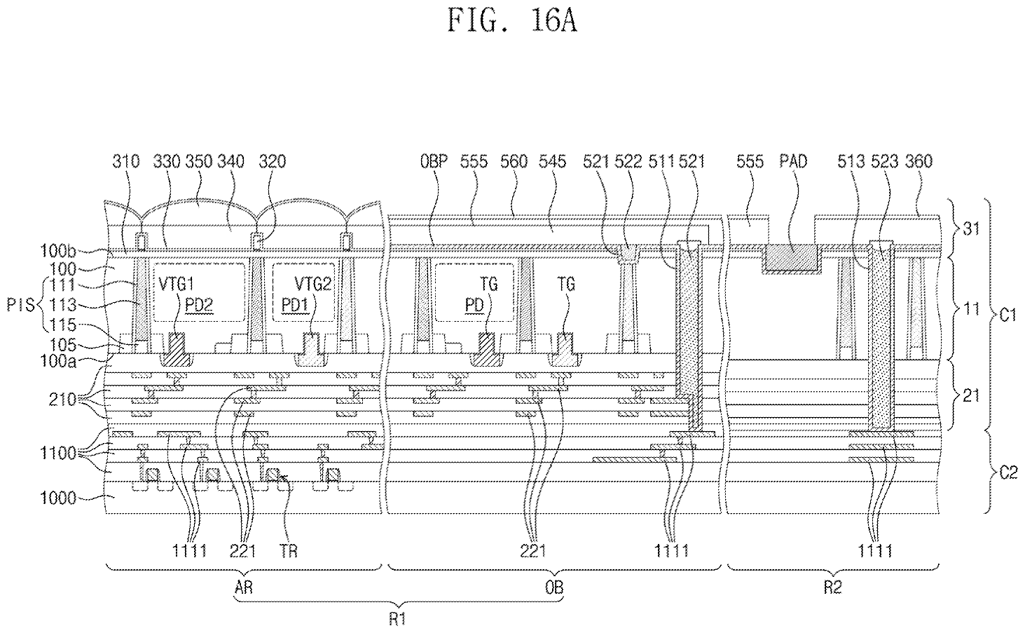

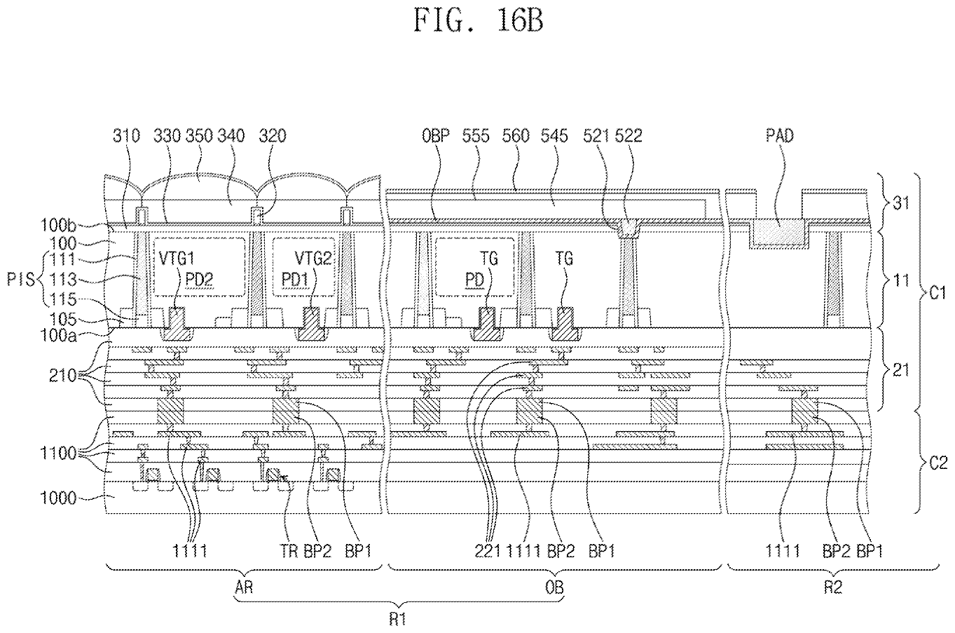

FIGS. 16A and 16B illustrate cross-sectional views showing an image sensor according to some embodiments of the disclosure.

Referring to FIG. 16A, an image sensor may include a sensor chip C1 and a logic chip C2. The sensor chip C1 may include a pixel array region R1 and a pad region R2.

The pixel array region R1 may include a plurality of unit pixels that are two-dimensionally arranged along the first direction D1 and the second direction D2 that intersect each other, as discussed above. Each of the unit pixels may include a photoelectric conversion element and pixel transistors. Each unit pixel P of the pixel array region R1 may output an electrical signal generated from incident light.

The pixel array region R1 may include a light-receiving region AR and a light-shielding region OB. When viewed in plan, the light-shielding region OB may surround the light-receiving region AR (see, e.g., FIGS. 15A and 15B). For example, when viewed in plan, the light-shielding region OB may be disposed on an upside, downside, left-side, and right-side of the light-receiving region AR. The light-shielding region OB may include reference pixels on which no or little light is incident, and an amount of charges sensed in the unit pixels of the light-receiving region AR may be compared with a reference amount of charges occurring at reference pixels, which may result in obtaining magnitudes of electrical signals sensed in the unit pixels.

The pad region R2 may include a plurality of conductive pads PAD used to input and output control signals and photoelectric signals. For easy connection with external devices, the pad region R2 may surround the pixel array region R1, in a plan view. The conductive pads PAD may allow an external device to receive electrical signals generated from the unit pixels.

The sensor chip C1 may include a photoelectric conversion layer 11 between a readout circuit layer 21 and an optical transmission layer 31, in a vertical direction. As mentioned above, the photoelectric conversion layer 11 of the sensor chip C1 may include a semiconductor substrate 100, a pixel isolation structure PIS that defines pixel regions, and photoelectric conversion regions PD1 and PD2. On the light-receiving region AR, the sensor chip C1 may have technical characteristics the same as those of the image sensor discussed above.

The pixel isolation structure PIS may extend from the light-receiving region AR toward the light-shielding region OB. A portion of the pixel isolation structure PIS may be electrically connected to a contact plug 522 on the light-shielding region OB.

A planarization dielectric layer 310 may extend from the light-receiving region AR toward the light-shielding region OB and the pad region R2.

On the light-shielding region OB, a light-shielding pattern OBP may be disposed on the planarization dielectric layer 310. The light-shielding pattern OBP may not allow light to travel toward photoelectric conversion regions PD provided on the light-shielding region OB. On reference pixel regions of the light-shielding region OB, the photoelectric conversion regions PD may output noise signals without outputting photoelectric signals. The noise signals may be generated from electrons produced due to heat or dark current. The light-shielding pattern OBP may include metal, such as tungsten, copper, aluminum, or any alloy thereof.

A filtering layer 545 may be provided on the light-shielding pattern OBP. The filtering layer 545 may block light whose wavelength is different from that of light produced from the color filters 340. For example, the filtering layer 545 may block an infrared ray. The filtering layer 545 may include a blue color filter, but the disclosure is not limited thereto.

On the light-shielding region OB, a first through conductive pattern 511 may penetrate the semiconductor substrate 100 to come into electrical connection with a metal line 221 of the readout circuit layer 21 and a wiring structure 1111 of the logic chip C2. The first through conductive pattern 511 may have a first bottom surface and a second bottom surface that are located at different levels. A first buried pattern 521 may be provided in the first through conductive pattern 511. The first buried pattern 521 may include a low-refractive material and may have dielectric properties.

On the pad region R2, the conductive pads PAD may be provided on a second surface 100b of the semiconductor substrate 100. The conductive pads PAD may be buried in the second surface 100b of the semiconductor substrate 100. For example, on the pad region R2, the conductive pads PAD may be provided in pad trenches formed on the second surface 100b of the semiconductor substrate 100. The conductive pads PAD may include metal, such as aluminum, copper, tungsten, titanium, tantalum, or any alloy thereof. In a mounting process of the image sensor, bonding wires may be bonded to the conductive pads PAD. The conductive pads PAD may be electrically connected through the bonding wires to an external device.

On the pad region R2, a second through conductive pattern 513 may penetrate the semiconductor substrate 100 to come into electrical connection with the wiring structure 1111 of the logic chip 2. The second through conductive pattern 513 may extend onto the second surface 100b of the semiconductor substrate 100 to come into electrical connection with the conductive pads PAD. A portion of the second through conductive pattern 513 may cover a bottom surface and a sidewall of the conductive pad PAD.

A second buried pattern 523 may be provided in the second through conductive pattern 513. The second buried pattern 523 may include a low-refractive material and may have dielectric properties. On the pad region R2, the pixel isolation structure PIS may be provided around the second through conductive pattern 513.

The logic chip C2 may include a logic semiconductor substrate 1000, logic circuits TR, wiring structures 1111 connected to the logic circuits, and logic interlayer dielectric layers 1100. An uppermost one of the logic interlayer dielectric layers 1100 may be in contact with the readout circuit layer 21 of the sensor chip C1. The logic chip C2 may be electrically connected to the sensor chip C1 through the first through conductive pattern 511 and the second through conductive pattern 513.

In an embodiment, it is described above that the sensor chip C1 and the logic chip C2 are electrically connected to each other through the first and second through conductive patterns 511 and 513, but the disclosure is not limited thereto.

According to the embodiment shown in FIG. 16B, the first and second through conductive patterns shown in FIG. 16A may be omitted, and the sensor chip C1 and the logic chip C2 may be electrically connected to each other through direct contact between bonding pads BP1 and BP2 that are provided at uppermost metal layers of the sensor chip C1 and the logic chip C2.

For example, the image sensor may be configured such that the sensor chip C1 may include first bonding pads BP1 provided at an uppermost metal layer of the readout circuit layer 21, and that the logic chip C2 may include second bonding pads BP2 provided at an uppermost metal layer of the wiring structure 1111. The first and second bonding pads BP1 and BP2 may include, for example, at least one selected from tungsten (W), aluminum (Al), copper (Cu), tungsten nitride (WN), tantalum nitride (TaN), and titanium nitride (TiN).

A hybrid bonding manner may be employed to directly and electrically connect the first bonding pads BP1 of the sensor chip C1 to the second bonding pads BP2 of the logic chip C2. The hybrid bonding may denote that two components of the same kind are merged at an interface therebetween. For example, when the first and second bonding pads BP1 and BP2 are formed of copper, a copper-to-copper bonding may be employed to physically and electrically connect the first and second bonding pads BP1 and BP2 to each other. In addition, a dielectric-to-dielectric bonding may be adopted to couple a surface of a dielectric layer included in the sensor chip C1 to a surface of a dielectric layer included in the logic chip C2.

According to some embodiments of the disclosure, a pixel isolation structure may be disposed between first and second photoelectric conversion regions whose sizes are different from each other, and a switching element may be provided between charge detection nodes that electrically connect to each other the first and second photoelectric conversion regions.

Therefore, when an effective integration time (EIT) is increased to achieve a high dynamic range (HDR), photo-charges may be prevented from overflowing from a first photoelectric conversion region having high sensitivity into a second photoelectric conversion region having low sensitivity.

An image sensor according to some embodiments may improve in blooming properties while obtaining a high dynamic range, and thus the image sensor may increase in signal-to-noise ratio (SNR).

Although the disclosure has been described in connection with some embodiments of the disclosure illustrated in the accompanying drawings, it will be understood to those skilled in the art that various changes and modifications may be made without departing from the technical spirit and essential feature of the disclosure. It will be apparent to those skilled in the art that various substitution, modifications, and changes may be thereto without departing from the scope and spirit of the disclosure.

What is claimed is:

1. An image sensor, comprising:
a semiconductor substrate comprising a first pixel region and a second pixel region;
a first photoelectric conversion element on the first pixel region;
a second photoelectric conversion element on the second pixel region;
a pixel isolation structure between the first photoelectric conversion element and the second photoelectric conversion element;
a first floating diffusion region on the first pixel region;
a first transfer gate electrode between the first photoelectric conversion element and the first floating diffusion region;
a second floating diffusion region on the second pixel region;
a second transfer gate electrode between the second photoelectric conversion element and the second floating diffusion region;
a first charge storage region on the first pixel region;
a second charge storage region on the second pixel region;
a first switching element between the first floating diffusion region and the first charge storage region; and
a second switching element between the second floating diffusion region and the second charge storage region.

2. The image sensor of claim 1, wherein a width of the second photoelectric conversion element is less than a width of the first photoelectric conversion element.

3. The image sensor of claim 1, wherein
the pixel isolation structure vertically extends from a first surface of the semiconductor substrate toward a second surface of the semiconductor substrate opposite to the first surface.

4. The image sensor of claim 1, wherein, when viewed in plan, the pixel isolation structure surrounds each of the first pixel region and the second pixel region.

5. The image sensor of claim 1, wherein each of the first transfer gate electrode and the second transfer gate electrode vertically penetrates a portion of the semiconductor substrate.

6. The image sensor of claim 1, further comprising a capacitor connected to the second floating diffusion region.

7. The image sensor of claim 1, further comprising:
a source follower transistor that amplifies a signal detected from the first floating diffusion region and outputs a pixel signal; and
a selection transistor that controls a connection between the source follower transistor and an output line.

8. The image sensor of claim 1, further comprising a reset transistor connected to the first charge storage region and to the second charge storage region.

9. The image sensor of claim 1, further comprising a color filter on both of the first pixel region and the second pixel region.

10. An image sensor, comprising:
a semiconductor substrate comprising a first pixel region and a second pixel region, the semiconductor substrate having a first conductivity type;
a first photoelectric conversion element on the first pixel region, the first photoelectric conversion element having a second conductivity type;
a second photoelectric conversion element on the second pixel region, the second photoelectric conversion element having the second conductivity type;
a pixel isolation structure between the first photoelectric conversion element and the second photoelectric conversion element;
a first charge storage region on the first pixel region, the first charge storage region having the second conductivity type;
a second charge storage region on the second pixel region, the second charge storage region having the second conductivity type;
a first well impurity region in the semiconductor substrate between the first charge storage region and the first photoelectric conversion element, the first well impurity region having the first conductivity type and overlapping a portion of the first photoelectric conversion element; and
a second well impurity region in the semiconductor substrate between the second charge storage region and the second photoelectric conversion element, the second well impurity region having the first conductivity type and overlapping a portion of the second photoelectric conversion element,
wherein a width of the second photoelectric conversion element is less than a width of the first photoelectric conversion element.

11. The image sensor of claim 10, further comprising:
a first floating diffusion region on the first pixel region and spaced apart from the first charge storage region;
a first transfer gate electrode between the first photoelectric conversion element and the first floating diffusion region;
a second floating diffusion region on the second pixel region and spaced apart from the second charge storage region; and
a second transfer gate electrode between the second photoelectric conversion element and the second floating diffusion region,
wherein the first floating diffusion region and the first transfer gate electrode are spaced apart from the first well impurity region, and
wherein the second floating diffusion region and the second transfer gate electrode are spaced apart from the second well impurity region.

12. The image sensor of claim 11, further comprising a capacitor connected to the second floating diffusion region.

13. The image sensor of claim 11, further comprising a first switching element between the first floating diffusion region and the first charge storage region.

14. The image sensor of claim 11, further comprising a second switching element between the second floating diffusion region and the second charge storage region.

15. The image sensor of claim 11, wherein each of the first transfer gate electrode and the second transfer gate electrode vertically penetrates a portion of the semiconductor substrate.

16. The image sensor of claim 10, wherein, when viewed in plan, the pixel isolation structure surrounds each of the first pixel region and the second pixel region.

17. An image sensor, comprising:
a semiconductor substrate comprising a first pixel region and a second pixel region, the semiconductor substrate having a first conductivity type;
a first photoelectric conversion element on the first pixel region, the first photoelectric conversion element having a second conductivity type;
a second photoelectric conversion element on the second pixel region, the second photoelectric conversion element having the second conductivity type;
a pixel isolation structure between the first photoelectric conversion element and the second photoelectric conversion element;
a first floating diffusion region on the first pixel region, the first floating diffusion region having the second conductivity type;
a first transfer gate electrode between the first photoelectric conversion element and the first floating diffusion region;
a first charge storage region on the first pixel region, the first charge storage region having the second conductivity type;
a first switching element between the first floating diffusion region and the first charge storage region;
a second floating diffusion region on the second pixel region, the second floating diffusion region having the second conductivity type;
a second transfer gate electrode between the second photoelectric conversion element and the second floating diffusion region;
a second charge storage region on the second pixel region, the second charge storage region having the second conductivity type;
a second switching element between the second floating diffusion region and the second charge storage region;
a first well impurity region in the semiconductor substrate between the first charge storage region and the first photoelectric conversion element, the first well impurity region having the first conductivity type and overlapping a portion of the first photoelectric conversion element;
a second well impurity region in the semiconductor substrate between the second charge storage region and the second photoelectric conversion element, the second well impurity region having the first conductivity type and overlapping a portion of the second photoelectric conversion element;
a conductive line that connects the first charge storage region to the second charge storage region; and
a capacitor connected to the second floating diffusion region.

18. The image sensor of claim 17, further comprising:
a source follower transistor that amplifies a signal detected from the first floating diffusion region and outputs a pixel signal; and
a selection transistor that controls a connection between the source follower transistor and an output line.

19. The image sensor of claim 17, further comprising a reset transistor connected in common to the first charge storage region and the second charge storage region.

20. The image sensor of claim 17, further comprising a color filter on both of the first pixel region and the second pixel region.
